(19) United States
(12) Patent Application Publication
(10) Pub. No.: US 2026/0261782 A1
(43) Pub. Date: Sep. 3, 2026

(54) SOLID-STATE IMAGING DEVICE

(71) Applicant: Nuvoton Technology Corporation Japan, Kyoto (JP)

(72) Inventors: Dai ICHIRYU, Kyoto (JP); Wataru FUNAMIZU, Kyoto (JP)

(21) Appl. No.: 19/655,272

(22) Filed: Apr. 22, 2026

Related U.S. Application Data
(63) Continuation of application No. PCT/JP2024/038236, filed on Oct. 25, 2024.
(60) Provisional application No. 63/594,315, filed on Oct. 30, 2023.

(51) Int. Cl. H04N 25/78; G11C 27/02; H03M 1/12; H04N 25/709

(52) U.S. Cl. CPC H04N 25/78; G11C 27/024; H03M 1/1245; H04N 25/709

(57) ABSTRACT

A solid-state imaging device includes a sample-and-hold circuit. The sample-and-hold circuit includes: a first capacitor; a second capacitor; a first buffer having an output connected to an analog-to-digital (AD) conversion circuit; a first input switch disposed between a vertical signal line and the first capacitor; a second input switch disposed between the vertical signal line and the second capacitor; a first output switch disposed between the first capacitor and an input of the first buffer; and a second output switch disposed between the second capacitor and the input of the first buffer. In a plan view, the first output switch and the first buffer are adjacent to each other in a column direction of a pixel array, and the second output switch and the first buffer are adjacent to each other in the column direction of the pixel array.

### CROSS REFERENCE TO RELATED APPLICATIONS

This is a continuation application of PCT International Patent Application No. PCT/JP2024/038236 filed on October 25, 2024, designating the United States of America, which is based on and claims priority of U.S. Provisional Patent Application No. 63/594315 filed on October 30, 2023. The entire disclosures of the above-identified applications, including the specifications, drawings and claims are incorporated herein by reference in their entirety.

### FIELD

The present disclosure relates to solid-state imaging devices.

### BACKGROUND

Solid-state imaging devices including sample-and-hold circuits have been known.

### Citation List

### Patent Literature

PTL 1: Japanese Unexamined Patent Application Publication No. 2008-125046

PTL 2: WO Publication No. 2023/063024

### SUMMARY

### Technical Problem

In order to achieve a high-speed imaging operation by pipeline-controlling the readout of pixel signals from pixels, conventional solid-state imaging devices include sample-and-hold circuits each of which includes a plurality of capacitors arranged in parallel to each other (e.g., refer to Patent Literatures (PTLs) 1 and 2).

On the other hand, there has been a demand for higher captured image quality in solid-state imaging devices.

In view of this, the present disclosure provides a solid-state imaging device that makes it possible to achieve higher captured image quality while achieving a high-speed imaging operation.

### Solution to Problem

A solid-state imaging device according to one aspect of the present disclosure is a solid-state imaging device that includes: a pixel array in which a plurality of pixels are arranged in rows and columns; a vertical signal line through which a pixel signal outputted from at least one of the plurality of pixels is transmitted, the vertical signal line extending in a column direction of the pixel array; a sample-and-hold circuit that holds the pixel signal transmitted through the vertical signal line; and an analog-to-digital (AD) conversion circuit that performs AD conversion on the pixel signal held by the sample-and-hold circuit. The sample-and-hold circuit includes: a first capacitor; a second capacitor that has a capacitance equal to a capacitance of the first capacitor; a first buffer that has an output connected to the AD conversion circuit; a first input switch that is disposed in an electrical path between the vertical signal line and the first capacitor; a second input switch that is disposed in an electrical path between the vertical signal line and the second capacitor; a first output switch that is disposed in an electrical path between the first capacitor and an input of the first buffer; and a second output switch that is disposed in an electrical path between the second capacitor and the input of the first buffer. In a plan view of the pixel array: the first output switch and the first buffer are adjacent to each other in the column direction; and the second output switch and the first buffer are adjacent to each other in the column direction.

A solid-state imaging device according to one aspect of the present disclosure is a solid-state imaging device that includes: a pixel array in which a plurality of pixels are arranged in rows and columns; a vertical signal line through which a pixel signal outputted from at least one of the plurality of pixels is transmitted, the vertical signal line extending in a column direction of the pixel array; a sample-and-hold circuit that holds the pixel signal transmitted through the vertical signal line; and an analog-to-digital (AD) conversion circuit that performs AD conversion on the pixel signal held by the sample-and-hold circuit. The sample-and-hold circuit includes: a first capacitor; a second capacitor that has a capacitance equal to a capacitance of the first capacitor; a third capacitor that has a capacitance equal to the capacitance of the first capacitor; a first buffer that has an output connected to the AD conversion circuit; a second buffer that has an output connected to the AD conversion circuit; a first input switch that is disposed in an electrical path between the vertical signal line and the first capacitor; a second input switch that is disposed in an electrical path between the vertical signal line and the second capacitor; a third input switch that is disposed in an electrical path between the vertical signal line and the third capacitor; a first output switch that is disposed in an electrical path between the first capacitor and an input of the first buffer; a second output switch that is disposed in an electrical path between the second capacitor and the input of the first buffer; a third output switch that is disposed in an electrical path between the second capacitor and an input of the second buffer; and a fourth output switch that is disposed in an electrical path between the third capacitor and the input of the second buffer. In a plan view of the pixel array: the first output switch and the first buffer are adjacent to each other in the column direction; the second output switch and the first buffer are adjacent to each other in the column direction; the third output switch and the second buffer are adjacent to each other in the column direction; and the fourth output switch and the second buffer are adjacent to each other in the column direction.

A solid-state imaging device according to one aspect of the present disclosure is a solid-state imaging device that includes: a pixel array in which a plurality of pixels are arranged in rows and columns; a first vertical signal line through which a first pixel signal outputted from at least one of the plurality of pixels is transmitted, the first vertical signal line extending in a column direction of the pixel array; a second vertical signal line through which a second pixel signal outputted from at least one of the plurality of pixels is transmitted, the second vertical signal line extending in the column direction, the second pixel signal having a gain higher than a gain of the first pixel signal; a sample-and-hold circuit that holds the first pixel signal transmitted through the first vertical signal line and the second pixel signal transmitted through the second vertical signal line; and an analog-to-digital (AD) conversion circuit that performs AD conversion on the first pixel signal and the second pixel signal that are held by the sample-and-hold circuit. The sample-and-hold circuit includes: a first capacitor; a second capacitor; a buffer that has an output connected to the AD conversion circuit; a first input switch that is disposed in an electrical path between the first vertical signal line and the first capacitor; a second input switch that is disposed in an electrical path between the second vertical signal line and the second capacitor; a first output switch that is disposed in an electrical path between the first capacitor and an input of the buffer; and a second output switch that is disposed in an electrical path between the second capacitor and the input of the buffer. In a plan view of the pixel array, a distance between the first output switch and the buffer in the column direction is shorter than a distance between the second output switch and the buffer in the column direction, and the first capacitor has a capacitance smaller than a capacitance of the second capacitor.

### Advantageous Effects

The solid-state imaging device according to one aspect of the present disclosure makes it possible to achieve higher captured image quality while achieving a high-speed imaging operation.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a block diagram illustrating a configuration of a solid-state imaging device according to Embodiment 1.

FIG. 2 is a circuit diagram illustrating an exemplary circuit configuration of a sample-and-hold circuit according to Embodiment 1.

FIG. 3 is a plan-view schematic diagram illustrating an exemplary physical configuration of the sample-and-hold circuit according to Embodiment 1.

FIG. 4 is a circuit diagram illustrating an exemplary circuit configuration of the sample-and-hold circuit according to Embodiment 1.

FIG. 5 is a circuit diagram illustrating an exemplary circuit configuration of the sample-and-hold circuit according to Embodiment 1.

FIG. 6 is a plan-view schematic diagram illustrating an exemplary physical configuration of the sample-and-hold circuit according to Embodiment 1.

FIG. 7 is a circuit diagram illustrating an exemplary circuit configuration of the sample-and-hold circuit according to Embodiment 1.

FIG. 8 is a circuit diagram illustrating an exemplary circuit configuration of the sample-and-hold circuit according to Embodiment 1.

FIG. 9 is a plan-view schematic diagram illustrating an exemplary physical configuration of the sample-and-hold circuit according to Embodiment 1.

FIG. 10 is a circuit diagram illustrating an exemplary circuit configuration of the sample-and-hold circuit according to Embodiment 1.

FIG. 11 is a circuit diagram illustrating an exemplary circuit configuration of the sample-and-hold circuit according to Embodiment 1.

FIG. 12 is a plan-view schematic diagram illustrating an exemplary physical configuration of the sample-and-hold circuit according to Embodiment 1.

FIG. 13 is a circuit diagram illustrating an exemplary circuit configuration of the sample-and-hold circuit according to Embodiment 1.

FIG. 14 is a timing chart for first readout pipeline control processing according to Embodiment 1.

FIG. 15 is a circuit diagram illustrating an exemplary circuit configuration of a sample-and-hold circuit according to Variation 1.

FIG. 16 is a circuit diagram illustrating an exemplary circuit configuration of a sample-and-hold circuit according to Variation 2.

FIG. 17 is a timing chart for exemplary operations performed by a solid-state imaging device according to Variation 2.

FIG. 18 is a block diagram illustrating a configuration of a solid-state imaging device according to Embodiment 2.

FIG. 19 is a circuit diagram illustrating an exemplary circuit configuration of a sample-and-hold circuit according to Embodiment 2.

FIG. 20 is a plan-view schematic diagram illustrating an exemplary physical configuration of the sample-and-hold circuit according to Embodiment 2.

FIG. 21 is a circuit diagram illustrating an exemplary circuit configuration of the sample-and-hold circuit according to Embodiment 2.

FIG. 22 is a circuit diagram illustrating an exemplary circuit configuration of the sample-and-hold circuit according to Embodiment 2.

FIG. 23 is a plan-view schematic diagram illustrating an exemplary physical configuration of the sample-and-hold circuit according to Embodiment 2.

FIG. 24 is a timing chart for exemplary operations performed by the solid-state imaging device according to Embodiment 2.

FIG. 25 is a circuit diagram illustrating an exemplary circuit configuration of the sample-and-hold circuit according to Embodiment 2.

FIG. 26 is a circuit diagram illustrating an exemplary circuit configuration of the sample-and-hold circuit according to Embodiment 2.

FIG. 27 is a plan-view schematic diagram illustrating an exemplary physical configuration of the sample-and-hold circuit according to Embodiment 2.

FIG. 28 is a plan-view schematic diagram illustrating an exemplary physical configuration of the sample-and-hold circuit according to Embodiment 2.

FIG. 29 is a timing chart for second readout pipeline control processing according to Embodiment 2.

FIG. 30 is a circuit diagram illustrating an exemplary circuit configuration of a sample-and-hold circuit according to a variation.

FIG. 31 is a circuit diagram illustrating an exemplary circuit configuration of a sample-and-hold circuit according to a variation.

### DESCRIPTION OF EMBODIMENTS

### Circumstances Leading to One Aspect of the Present Disclosure

Since conventional solid-state imaging devices include sample-and-hold circuits each of which includes: a plurality of capacitors that hold pixel signals read out from pixels and are arranged in parallel to each other; a plurality of switches that select one capacitor exclusively from the plurality of capacitors; and a buffer that outputs, to an AD conversion circuit, a voltage corresponding to pixel signals held by the one capacitor selected, the conventional solid-state imaging devices make it possible to achieve a high-speed imaging operation by pipeline-controlling the readout of the pixel signals from the pixels.

The inventors diligently carried out experiments and studies to achieve higher captured image quality in the solid-state imaging devices thus configured. As a result, the inventors gained knowledge about factors that impede the achievement of higher captured image quality in the solid-state imaging devices thus configured.

In other words, the inventors gained (1) knowledge that since there is a parasitic capacitance in an electrical path between a capacitor and a buffer via a switch, captured image quality deteriorates due to charge redistribution between a capacitance of the capacitor and the parasitic capacitance caused by the operation of the switch, and (2) knowledge that captured image quality deteriorates due to variations in parasitic capacitance in each of electrical paths between a plurality of capacitors and a buffer.

Additionally, the inventors gained knowledge that when a plurality of capacitors include a capacitor having a larger capacitance and a capacitor having a smaller capacitance, the capacitor having the smaller capacitance has a more negative impact on the deterioration in captured image quality due to parasitic capacitances in electrical paths between the capacitors and a buffer than the capacitor having the larger capacitance.

Then, the inventors carried out further experiments and studies, based on these pieces of knowledge. As a result, the inventors have conceived a solid-state imaging device according to one aspect of the present disclosure.

A solid-state imaging device according to one aspect of the present disclosure is a solid-state imaging device that includes: a pixel array in which a plurality of pixels are arranged in rows and columns; a vertical signal line through which a pixel signal outputted from at least one of the plurality of pixels is transmitted, the vertical signal line extending in a column direction of the pixel array; a sample-and-hold circuit that holds the pixel signal transmitted through the vertical signal line; and an analog-to-digital (AD) conversion circuit that performs AD conversion on the pixel signal held by the sample-and-hold circuit. The sample-and-hold circuit includes: a first capacitor; a second capacitor that has a capacitance equal to a capacitance of the first capacitor; a first buffer that has an output connected to the AD conversion circuit; a first input switch that is disposed in an electrical path between the vertical signal line and the first capacitor; a second input switch that is disposed in an electrical path between the vertical signal line and the second capacitor; a first output switch that is disposed in an electrical path between the first capacitor and an input of the first buffer; and a second output switch that is disposed in an electrical path between the second capacitor and the input of the first buffer. In a plan view of the pixel array: the first output switch and the first buffer are adjacent to each other in the column direction; and the second output switch and the first buffer are adjacent to each other in the column direction.

The solid-state imaging device thus configured makes it possible to minimize a parasitic capacitance in an electrical path between the first output switch and the input of the first buffer, and a parasitic capacitance in an electrical path between the second output switch and the input of the first buffer.

Additionally, the solid-state imaging device thus configured makes it possible to reduce relative variations between a parasitic capacitance in an electrical path between the first input switch and the first output switch and a parasitic capacitance in an electrical path between the second input switch and the second output switch.

Moreover, the solid-state imaging device thus configured includes the sample-and-hold circuit that includes the first capacitor and the second capacitor arranged in parallel to each other.

Accordingly, the solid-state imaging device thus configured makes it possible to achieve higher captured image quality while achieving a high-speed imaging operation.

Furthermore, the sample-and-hold circuit may further include: a third capacitor that has a capacitance equal to the capacitance of the first capacitor; a fourth capacitor that has a capacitance equal to the capacitance of the first capacitor; a second buffer that has an output connected to the AD conversion circuit; a third input switch that is disposed in an electrical path between the vertical signal line and the third capacitor; a fourth input switch that is disposed in an electrical path between the vertical signal line and the fourth capacitor; a third output switch that is disposed in an electrical path between the third capacitor and an input of the second buffer; and a fourth output switch that is disposed in an electrical path between the fourth capacitor and the input of the second buffer. In the plan view of the pixel array: the third output switch and the second buffer may be adjacent to each other in the column direction; and the fourth output switch and the second buffer may be adjacent to each other in the column direction.

The solid-state imaging device thus configured makes it possible to minimize a parasitic capacitance in an electrical path between the third output switch and the input of the second buffer, and a parasitic capacitance in an electrical path between the fourth output switch and the input of the second buffer.

Additionally, the solid-state imaging device thus configured makes it possible to reduce relative variations among a parasitic capacitance in an electrical path between the first input switch and the first output switch, a parasitic capacitance in an electrical path between the second input switch and the second output switch, a parasitic capacitance in an electrical path between the third input switch and the third output switch, a parasitic capacitance in an electrical path between the fourth input switch and the fourth output switch.

Moreover, the solid-state imaging device thus configured includes the sample-and-hold circuit that includes the first capacitor, the second capacitor, the third capacitor, and the fourth capacitor arranged in parallel to each other.

Accordingly, the solid-state imaging device thus configured makes it possible to achieve the higher captured image quality while achieving the high-speed imaging operation.

A solid-state imaging device according to one aspect of the present disclosure is a solid-state imaging device that includes: a pixel array in which a plurality of pixels are arranged in rows and columns; a vertical signal line through which a pixel signal outputted from at least one of the plurality of pixels is transmitted, the vertical signal line extending in a column direction of the pixel array; a sample-and-hold circuit that holds the pixel signal transmitted through the vertical signal line; and an analog-to-digital (AD) conversion circuit that performs AD conversion on the pixel signal held by the sample-and-hold circuit. The sample-and-hold circuit includes: a first capacitor; a second capacitor that has a capacitance equal to a capacitance of the first capacitor; a third capacitor that has a capacitance equal to the capacitance of the first capacitor; a first buffer that has an output connected to the AD conversion circuit; a second buffer that has an output connected to the AD conversion circuit; a first input switch that is disposed in an electrical path between the vertical signal line and the first capacitor; a second input switch that is disposed in an electrical path between the vertical signal line and the second capacitor; a third input switch that is disposed in an electrical path between the vertical signal line and the third capacitor; a first output switch that is disposed in an electrical path between the first capacitor and an input of the first buffer; a second output switch that is disposed in an electrical path between the second capacitor and the input of the first buffer; a third output switch that is disposed in an electrical path between the second capacitor and an input of the second buffer; and a fourth output switch that is disposed in an electrical path between the third capacitor and the input of the second buffer. In a plan view of the pixel array: the first output switch and the first buffer are adjacent to each other in the column direction; the second output switch and the first buffer are adjacent to each other in the column direction; the third output switch and the second buffer are adjacent to each other in the column direction; and the fourth output switch and the second buffer are adjacent to each other in the column direction.

The solid-state imaging device thus configured makes it possible to minimize a parasitic capacitance in an electrical path between the first output switch and the input of the first buffer, a parasitic capacitance in an electrical path between the second output switch and the input of the first buffer, a parasitic capacitance in an electrical path between the third output switch and the input of the second buffer, and a parasitic capacitance in an electrical path between the fourth output switch and the input of the second buffer.

Additionally, the solid-state imaging device thus configured makes it possible to reduce relative variations among a parasitic capacitance in an electrical path between the first input switch and the first output switch, a parasitic capacitance in an electrical path between the second input switch and the second output switch, a parasitic capacitance in an electrical path between the second input switch and the third output switch, a parasitic capacitance in an electrical path between the third input switch and the fourth output switch.

Moreover, the solid-state imaging device thus configured includes the sample-and-hold circuit that includes the first capacitor, the second capacitor, and the third capacitor arranged in parallel to each other.

Accordingly, the solid-state imaging device thus configured makes it possible to achieve the higher captured image quality while achieving the high-speed imaging operation.

Furthermore, the sample-and-hold circuit may further include: a fourth capacitor that has a capacitance equal to the capacitance of the first capacitor; a fifth capacitor that has a capacitance equal to the capacitance of the first capacitor; a third buffer that has an output connected to the AD conversion circuit; a fourth input switch that is disposed in an electrical path between the vertical signal line and the fourth capacitor; a fifth input switch that is disposed in an electrical path between the vertical signal line and the fifth capacitor; a fifth output switch that is disposed in an electrical path between the fourth capacitor and an input of the third buffer; and a sixth output switch that is disposed in an electrical path between the fifth capacitor and the input of the third buffer. In the plan view of the pixel array: the fifth output switch and the third buffer may be adjacent to each other in the column direction; and the sixth output switch and the third buffer may be adjacent to each other in the column direction.

The solid-state imaging device thus configured makes it possible to minimize a parasitic capacitance in an electrical path between the fifth output switch and the input of the third buffer, and a parasitic capacitance in an electrical path between the sixth output switch and the input of the third buffer.

Additionally, the solid-state imaging device thus configured makes it possible to reduce relative variations among a parasitic capacitance in an electrical path between the first input switch and the first output switch, a parasitic capacitance in an electrical path between the second input switch and the second output switch, a parasitic capacitance in an electrical path between the second input switch and the third output switch, a parasitic capacitance in an electrical path between the third input switch and the fourth output switch, a parasitic capacitance in an electrical path between the fourth input switch and the fifth output switch, and a parasitic capacitance in an electrical path between the fifth input switch and the sixth output switch.

Moreover, the solid-state imaging device thus configured includes the sample-and-hold circuit that includes the first capacitor, the second capacitor, the third capacitor, the fourth capacitor, and the fifth capacitor arranged in parallel to each other.

Accordingly, the solid-state imaging device thus configured makes it possible to achieve the higher captured image quality while achieving the high-speed imaging operation.

A solid-state imaging device according to one aspect of the present disclosure is a solid-state imaging device that includes: a pixel array in which a plurality of pixels are arranged in rows and columns; a first vertical signal line through which a first pixel signal outputted from at least one of the plurality of pixels is transmitted, the first vertical signal line extending in a column direction of the pixel array; a second vertical signal line through which a second pixel signal outputted from at least one of the plurality of pixels is transmitted, the second vertical signal line extending in the column direction, the second pixel signal having a gain higher than a gain of the first pixel signal; a sample-and-hold circuit that holds the first pixel signal transmitted through the first vertical signal line and the second pixel signal transmitted through the second vertical signal line; and an analog-to-digital (AD) conversion circuit that performs AD conversion on the first pixel signal and the second pixel signal that are held by the sample-and-hold circuit. The sample-and-hold circuit includes: a first capacitor; a second capacitor; a buffer that has an output connected to the AD conversion circuit; a first input switch that is disposed in an electrical path between the first vertical signal line and the first capacitor; a second input switch that is disposed in an electrical path between the second vertical signal line and the second capacitor; a first output switch that is disposed in an electrical path between the first capacitor and an input of the buffer; and a second output switch that is disposed in an electrical path between the second capacitor and the input of the buffer. In a plan view of the pixel array, a distance between the first output switch and the buffer in the column direction is shorter than a distance between the second output switch and the buffer in the column direction, and the first capacitor has a capacitance smaller than a capacitance of the second capacitor.

The solid-state imaging device thus configured makes it possible to cause a parasitic capacitance between the first output switch and the input of the buffer in the electrical path between the first capacitor having a smaller capacitance and the input of the buffer to be smaller than a parasitic capacitance between the second output switch and the input of the buffer in the electrical path between the second capacitor having a larger capacitance and the input of the buffer. Accordingly, it is possible to reduce the impact of charge redistribution caused by the operation of at least one of the first output switch or the second output switch.

Moreover, the solid-state imaging device thus configured includes the sample-and-hold circuit that includes the first capacitor and the second capacitor arranged in parallel to each other.

Accordingly, the solid-state imaging device thus configured makes it possible to achieve the higher captured image quality while achieving the high-speed imaging operation.

Furthermore, the sample-and-hold circuit may further include: a third capacitor that has a capacitance equal to the capacitance of the first capacitor; a fourth capacitor that has a capacitance equal to the capacitance of the second capacitor; a third input switch that is disposed in an electrical path between the first vertical signal line and the third capacitor; a fourth input switch that is disposed in an electrical path between the second vertical signal line and the fourth capacitor; a third output switch that is disposed in an electrical path between the third capacitor and the input of the buffer; and a fourth output switch that is disposed in an electrical path between the fourth capacitor and the input of the buffer. In the plan view of the pixel array, a distance between the third output switch and the buffer in the column direction is shorter than a distance between the fourth output switch and the buffer in the column direction.

The solid-state imaging device thus configured makes it possible to cause a parasitic capacitance between the third output switch and the input of the buffer in the electrical path between the third capacitor having a smaller capacitance and the input of the buffer to be smaller than a parasitic capacitance between the fourth output switch and the input of the buffer in the electrical path between the fourth capacitor having a larger capacitance and the input of the buffer. Accordingly, it is possible to reduce the impact of charge redistribution caused by the operation of at least one of the third output switch or the fourth output switch.

Moreover, the solid-state imaging device thus configured includes the sample-and-hold circuit that includes the first capacitor, the second capacitor, the third capacitor, and the fourth capacitor arranged in parallel to each other.

Accordingly, the solid-state imaging device thus configured makes it possible to achieve the higher captured image quality while achieving the high-speed imaging operation.

Furthermore, the sample-and-hold circuit may further include: a first selector switch that is disposed in an electrical path between (i) the first output switch and the second output switch and (ii) the input of the buffer; and a second selector switch that is disposed in an electrical path between (i) the third output switch and the fourth output switch and (ii) the input of the buffer. In the plan view of the pixel array: the first selector switch and the buffer may be adjacent to each other in the column direction; and the second selector switch and the buffer may be adjacent to each other in the column direction.

This makes it possible to reduce a parasitic capacitance in an electrical path between (i) the first output switch and the second output switch and (ii) the input of the buffer, and a parasitic capacitance in an electrical path between (i) the third output switch and the fourth output switch and (ii) the input of the buffer, compared to a configuration without the first selector switch and the second selector switch.

Accordingly, the solid-state imaging device thus configured makes it possible to achieve the higher captured image quality while achieving the high-speed imaging operation.

Moreover, the sample-and-hold circuit may further include: a fixed voltage output circuit that outputs, to the first buffer, an operating voltage for causing the first buffer to operate, the operating voltage having a fixed electric potential; and a reset switch that is disposed in an electrical path between an output of the fixed voltage output circuit and the input of the first buffer.

Consequently, since the operating voltage of the first buffer becomes a fixed electric potential, it is possible to further stabilize the operation of the first buffer.

In addition, as a result, it is possible to stably reset the input of the first buffer to a fixed voltage.

Accordingly, it is possible to achieve significantly higher captured image quality.

Furthermore, the sample-and-hold circuit may further include: a fixed voltage output circuit that outputs, to the first buffer and the second buffer, an operating voltage for causing the first buffer and the second buffer to operate, the operating voltage having a fixed electric potential; a first reset switch that is disposed in an electrical path between an output of the fixed voltage output circuit and the input of the first buffer; and a second reset switch that is disposed in an electrical path between the output of the fixed voltage output circuit and the input of the second buffer.

Consequently, since the operating voltage of the first buffer and the operating voltage of the second buffer become a fixed electric potential, it is possible to further stabilize the operation of the first buffer and the operation of the second buffer.

In addition, as a result, it is possible to stably reset the input of the first buffer and the input of the second buffer to a fixed voltage.

Accordingly, it is possible to achieve significantly higher captured image quality.

Moreover, the sample-and-hold circuit may further include: a fixed voltage output circuit that outputs, to the buffer, an operating voltage for causing the buffer to operate, the operating voltage having a fixed electric potential; and a reset switch that is disposed in an electrical path between an output of the fixed voltage output circuit and the input of the buffer.

Consequently, since the operating voltage of the buffer becomes a fixed electric potential, it is possible to further stabilize the operation of the buffer.

In addition, as a result, it is possible to stably reset the input of the buffer to a fixed voltage.

Accordingly, it is possible to achieve significantly higher captured image quality.

Furthermore, the fixed voltage output circuit may include: a transistor that includes a drain connected to a power supply line and a source connected to the output of the fixed voltage output circuit; an electric-potential-holding capacitor that is connected to a gate of the transistor; and an electric-potential-holding switch that is disposed in an electrical path between the power supply line and the electric-potential-holding capacitor.

Accordingly, it is possible to achieve the fixed voltage output circuit using a relatively simple configuration.

Moreover, the sample-and-hold circuit may further include a pull-up or pull-down switch that adjusts the output of the fixed voltage output circuit.

Consequently, since it is possible to cause each of the buffers to operate at a pulled-up electric potential, it is possible to expand a dynamic range of the buffer.

For this reason, it is possible to improve the linearity of each buffer.

Accordingly, it is possible to achieve significantly higher captured image quality.

Hereinafter, specific examples of a solid-state imaging device according to one aspect of the present disclosure are described with reference to the Drawings. Each of the embodiments described below shows a specific example of the present disclosure. Accordingly, the numerical values, shapes, constituent elements, the arrangement and connection of the constituent elements, and steps (processes) and the order of steps, etc. shown in the following embodiments are mere examples, and are not intended to limit the present disclosure. In addition, each of the figures is a schematic diagram and is not necessarily a precise illustration. In each figure, the same reference signs are assigned to substantially the same constituent elements, and redundant portions of the description are omitted or simplified.

### EMBODIMENT 1

### 1.1. Configuration of solid-state imaging device

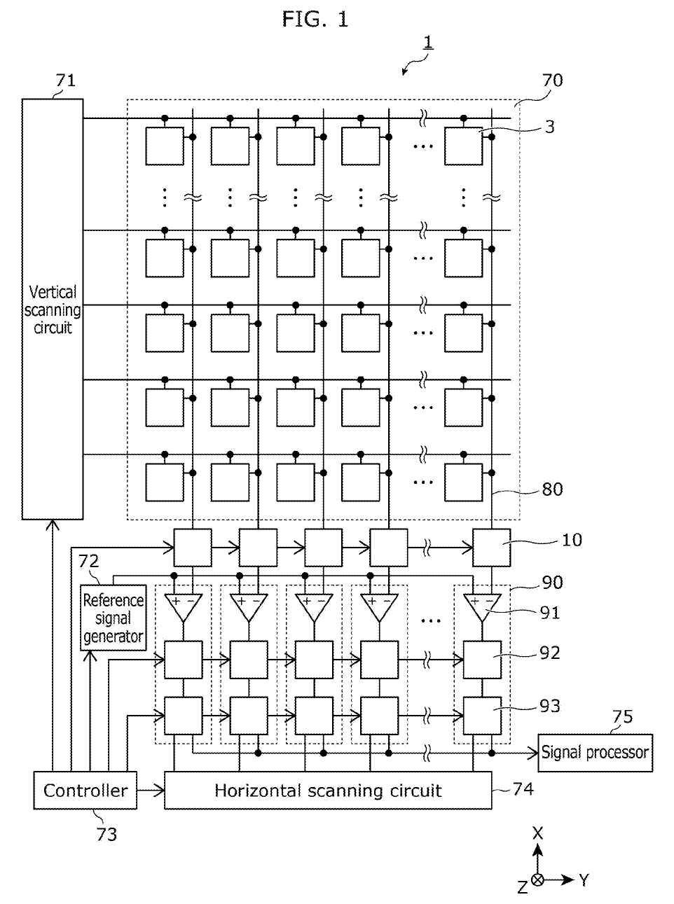

FIG. 1 is a block diagram illustrating a configuration of solid-state imaging device 1 according to Embodiment 1.

As shown in FIG. 1, solid-state imaging device 1 includes pixel array 70, vertical scanning circuit 71, reference signal generator 72, controller 73, horizontal scanning circuit 74, signal processor 75, a plurality of vertical signal lines 80, a plurality of sample-and-hold circuits 10, and a plurality of AD conversion circuits 90.

Pixel array 70 is configured by arranging a plurality of pixels 3 in m rows and n columns, where m is an integer greater than or equal to 2 and n is an integer greater than or equal to 2.

Pixel 3 includes: a photoelectric converter that converts exposed light into signal charge; and a signal charge holder that holds the signal charge generated by the photoelectric converter. Pixel 3 outputs a pixel signal corresponding to the signal charge held in the signal charge holder.

Each of the plurality of vertical signal lines 80 extends in a column direction (an X-axis direction in FIG. 1) of pixel array 70, is connected to m pixels 3 arranged in the column direction of pixel array 70, and is for transmitting a pixel signal outputted from at least one of m pixels 3 connected.

In other words, the number of the plurality of vertical signal lines 80 included in solid-state imaging device 1 is n that is equal to the number of columns of pixel array 70.

It should be noted that the number of columns of column circuits may be an integer multiple of the number of the columns of pixel array 70, where the multiple is, for example, 2, 3, or 4. In such a case, the number of the plurality of vertical signal lines 80 is an integer multiple of the n columns of pixel array 70. However, here, the following description assumes that the number of the plurality of vertical signal lines 80 is n that is equal to the number of the columns of pixel array 70.

By performing, for each row, sequential selective scan on the plurality of pixels 3 included in pixel array 70, vertical scanning circuit 71 causes each of n pixels 3 belonging to a row to be scanned to simultaneously output a pixel signal to a corresponding one of n vertical signal lines 80.

Reference signal generator 72 generates a reference ramp signal referred to by voltage comparator 91 to be described later for voltage comparison.

Controller 73 controls an operation timing of each of the constituent elements included in solid-state imaging device 1.

By performing sequential selective scan on n memories 93 to be described later, horizontal scanning circuit 74 outputs pixel data (to be described later) stored in memory 93 to signal processor 75 in sequence.

Signal processor 75 performs various types of signal processing on the pixel data outputted from horizontal scanning circuit 74 in sequence.

The plurality of sample-and-hold circuits 10 correspond to the plurality of vertical signal lines 80 on a one-to-one basis, and each of the plurality of sample-and-hold circuits 10 holds a pixel signal transmitted through corresponding vertical signal line 80.

In other words, the number of the plurality of sample-and-hold circuits 10 included in solid-state imaging device 1 is n that is equal to the number of the columns of pixel array 70.

It should be noted that the number of the columns of the column circuits may be an integer multiple of the number of the columns of pixel array 70, where the multiple is, for example, 2, 3, or 4. In such a case, the number of the plurality of sample-and-hold circuits 10 is an integer multiple of the n columns of pixel array 70. However, here, the following description assumes that the number of the plurality of sample-and-hold circuits 10 is n that is equal to the number of the columns of pixel array 70.

Sample-and-hold circuit 10 includes a plurality of capacitors that are for holding pixel signals and arranged in parallel to each other. To put it differently, sample-and-hold circuit 10 makes it possible to hold a plurality of pixel signals. In addition, sample-and-hold circuit 10 includes one or more buffers for buffering pixel signals held by the plurality of capacitors. Sample-and-hold circuit 10 outputs a signal corresponding to one of the pluralities of pixel signals held.

A specific configuration of sample-and-hold circuit 10 is described later.

The plurality of AD conversion circuits 90 correspond to the plurality of sample-and-hold circuits 10 on a one-to-one basis, and each of the plurality of AD conversion circuits 90 performs AD conversion on a signal outputted from corresponding sample-and-hold circuit 10.

In other words, the number of the plurality of AD conversion circuits 90 included in solid-state imaging device 1 is n that is equal to the number of the columns of pixel array 70.

It should be noted that the number of the columns of the column circuits may be an integer multiple of the number of the columns of pixel array 70, where the multiple is, for example, 2, 3, or 4. In such a case, the number of the plurality of AD conversion circuits 90 is an integer multiple of n that is the number of the columns of pixel array 70. However, here, the following description assumes that the number of the plurality of AD conversion circuits 90 is n that is equal to the number of the columns of pixel array 70.

As shown in FIG. 1, AD conversion circuit 90 includes voltage comparator 91, counter circuit 92, and memory 93.

Voltage comparator 91 compares the voltage of a reference ramp signal generated by reference signal generator 72 and the voltage of a signal outputted from sample-and-hold circuit 10.

Counter circuit 92 detects a count value when the comparison made by voltage comparator 91 indicates a match between the voltages.

The count value detected by counter circuit 92 is determined according to the value of a pixel signal held by corresponding sample-and-hold circuit 10. For this reason, the count value detected by counter circuit 92 is the value of a pixel signal digitized. It should be noted that the value of the pixel signal digitized is also referred to as “pixel data”.

Memory 93 stores a count value detected by counter circuit 92, that is, store pixel data.

It should be noted that when AD conversion is performed, digital correlated double sampling (digital CDS) processing is additionally performed, the digital CDS processing removing, for example, reset noise in pixel 3, fixed pattern noise fixed to pixel 3, and noise caused by AD conversion circuit 90 by calculating a difference between a result of AD conversion performed on a pixel signal outputted from pixel 3 in a reset state and a result of AD conversion performed on a pixel signal outputted from pixel 3 in an exposure state.

### 1.2. Configuration of sample-and-hold circuit

Hereinafter, a specific configuration of sample-and-hold circuit 10 is described.

As stated above, sample-and-hold circuit 10 includes a plurality of capacitors that are for holding pixel signals and arranged in parallel to each other.

First, a configuration of sample-and-hold circuit 10 when sample-and-hold circuit 10 includes two capacitors is described.

### 1.2.A. Configuration of sample-and-hold circuit including two capacitors

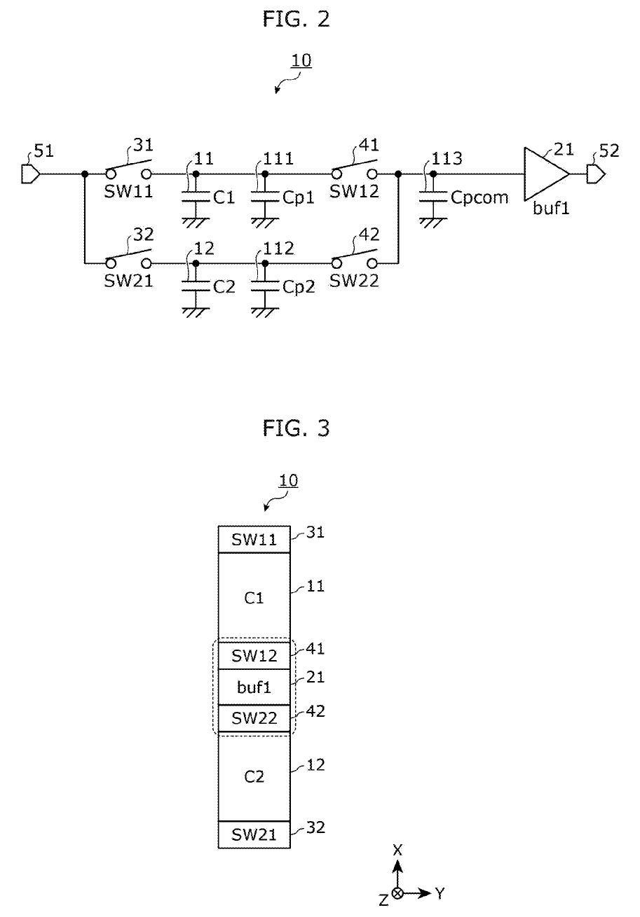

FIG. 2 is a circuit diagram illustrating an exemplary circuit configuration of sample-and-hold circuit 10 when sample-and-hold circuit 10 includes two capacitors.

As shown in FIG. 2, sample-and-hold circuit 10 includes first capacitor 11, second capacitor 12, first buffer 21, first input switch 31, second input switch 32, first output switch 41, second output switch 42, input 51, and output 52.

Input 51 is connected to vertical signal line 80.

Output 52 is connected to AD conversion circuit 90.

First capacitor 11 is a capacitor for holding pixel signals. First capacitor 11 is denoted by C1 in FIG. 2, circuit diagrams and plan views to be described later, etc.

Second capacitor 12 is a capacitor for holding pixel signals and has a capacitance equal to a capacitance of first capacitor 11. Second capacitor 12 is denoted by C2 in FIG. 2, the circuit diagrams and plan views to be described later, etc.

First buffer 21 is a buffer that has an output connected to output 52, that is, an output connected to AD conversion circuit 90 and is for buffering the pixel signals held by first capacitor 11 or the pixel signals held by second capacitor 12. First buffer 21 is denoted by buf1 in FIG. 2, the circuit diagrams and plan views to be described later, etc.

First input switch 31 is a switch that is connected to input 51 and first capacitor 11 and alternates between a conductive state and a non-conductive state to connect or disconnect input 51 and first capacitor 11. In other words, first input switch 31 is a switch that is disposed in an electrical path between vertical signal line 80 and first capacitor 11, and alternates between the conductive state and the non-conductive state to connect or disconnect vertical signal line 80 and first capacitor 11. First input switch 31 is denoted by SW11 in FIG. 2, the circuit diagrams and plan views to be described later, etc.

Second input switch 32 is a switch that is connected to input 51 and second capacitor 12 and alternates between the conductive state and the non-conductive state to connect or disconnect input 51 and second capacitor 12. In other words, second input switch 32 is a switch that is disposed in an electrical path between vertical signal line 80 and second capacitor 12, and alternates between the conductive state and the non-conductive state to connect or disconnect vertical signal line 80 and second capacitor 12. Second input switch 32 is denoted by SW21 in FIG. 2, the circuit diagrams and plan views to be described later, etc.

First output switch 41 is a switch that is connected to first capacitor 11 and an input of first buffer 21 and alternates between the conductive state and the non-conductive state to connect or disconnect first capacitor 11 and the input of first buffer 21. In other words, first output switch 41 is a switch that is disposed in an electrical path between first capacitor 11 and the input of first buffer 21, and alternates between the conductive state and the non-conductive state to connect or disconnect first capacitor 11 and the input of first buffer 21. First output switch 41 is denoted by SW12 in FIG. 2, the circuit diagrams and plan views to be described later, etc.

Second output switch 42 is a switch that is connected to second capacitor 12 and the input of first buffer 21 and alternates between the conductive state and the non-conductive state to connect or disconnect second capacitor 12 and the input of first buffer 21. In other words, second output switch 42 is a switch that is disposed in an electrical path between second capacitor 12 and the input of first buffer 21, and alternates between the conductive state and the non-conductive state to connect or disconnect second capacitor 12 and the input of first buffer 21. Second output switch 42 is denoted by SW22 in FIG. 2, the circuit diagrams and plan views to be described later, etc.

As shown in FIG. 2, in sample-and-hold circuit 10 shown in FIG. 2, parasitic capacitance 111 (denoted by Cp1 in FIG. 2) is in an electrical path between first input switch 31 and first output switch 41, parasitic capacitance 112 (denoted by Cp2 in FIG. 2) is in an electrical path between second input switch 32 and second output switch 42, and parasitic capacitance 113 (denoted by Cpcom in FIG. 2) is in an electrical path between (i) first output switch 41 and second output switch 42 and (ii) the input of first buffer 21.

It should be noted that although similar parasitic capacitances are in sample-and-hold circuit 10 etc. exemplified in the following description, these parasitic capacitances are omitted from the subsequent figures to avoid unnecessary complexity in the figures.

FIG. 3 is a plan-view schematic diagram illustrating an exemplary physical configuration of sample-and-hold circuit 10 shown in FIG. 2.

In FIG. 3, an X-axis direction is the column direction of pixel array 70, and a Y-axis direction is the row direction of pixel array 70. For this reason, FIG. 3 is a plan-view schematic diagram illustrating sample-and-hold circuit 10 in a plan view of pixel array 70.

As shown in FIG. 3, in a plan view of sample-and-hold circuit 10, that is, in the plan view of pixel array 70, first output switch 41 and first buffer 21 are adjacent to each other in the column direction (the X-axis direction in FIG. 3) of pixel array 70, and second output switch 42 and first buffer 21 are adjacent to each other in the column direction of pixel array 70.

Solid-state imaging device 1 including sample-and-hold circuit 10 thus configured makes it possible to minimize a parasitic capacitance in an electrical path between first output switch 41 and the input of first buffer 21, and a parasitic capacitance in an electrical path between second output switch 42 and the input of first buffer 21.

Moreover, solid-state imaging device 1 including sample-and-hold circuit 10 thus configured makes it possible to reduce relative variations between a parasitic capacitance in an electrical path between first input switch 31 and first output switch 41 and a parasitic capacitance in an electrical path between second input switch 32 and second output switch 42.

Furthermore, solid-state imaging device 1 including sample-and-hold circuit 10 thus configured includes sample-and-hold circuit 10 that includes first capacitor 11 and second capacitor 12 arranged in parallel to each other.

Accordingly, solid-state imaging device 1 including sample-and-hold circuit 10 thus configured makes it possible to achieve a higher captured image quality while achieving a high-speed imaging operation.

It should be noted that sample-and-hold circuit 10 may further include inputs of one or more buffers and one or more reset switches for resetting the plurality of capacitors.

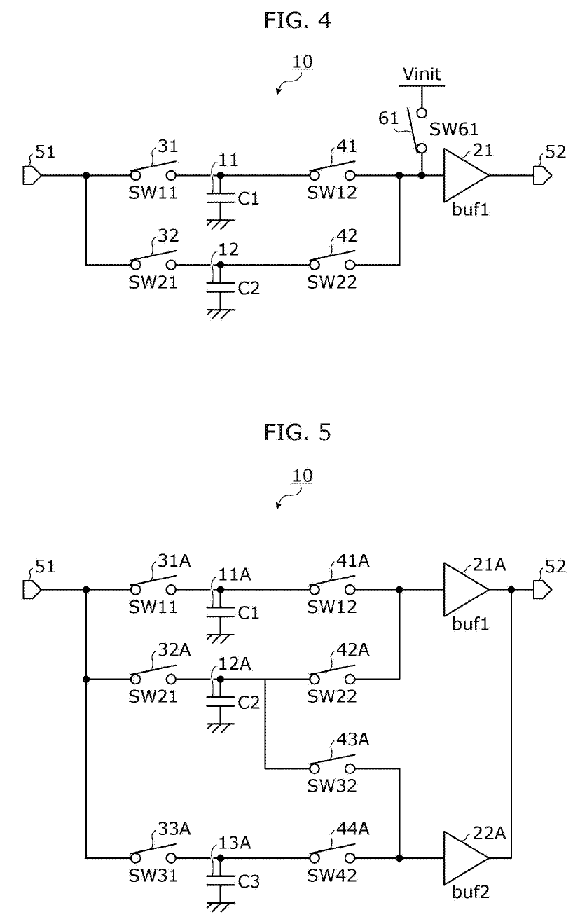

FIG. 4 is a circuit diagram illustrating an exemplary circuit configuration of sample-and-hold circuit 10 when sample-and-hold circuit 10 shown in FIG. 2 further includes first reset switch 61 for resetting the input of first buffer 21 to initialization voltage Vinit.

First reset switch 61 is a switch that is connected to an output of an initialization power source that supplies initialization voltage Vinit and the input of first buffer 21, and alternates between the conductive state and the non-conductive state to connect or disconnect the output of the initialization power source and the input of first buffer 21. In other words, first reset switch 61 is a switch that is disposed in an electrical path between the output of the initialization power source and the input of first buffer 21, and alternates between the conductive state and the non-conductive state to connect or disconnect the output of the initialization power source and the input of first buffer 21. First reset switch 61 is denoted by SW61 in FIG. 4, the circuit diagrams and plan views to be described later, etc.

By causing first reset switch 61 to be in the conductive state, solid-state imaging device 1 including sample-and-hold circuit 10 thus configured makes it possible to reset the input of first buffer 21 to initialization voltage Vinit.

Next, a configuration of sample-and-hold circuit 10 when sample-and-hold circuit 10 includes three capacitors is described.

### 1.2.B. Configuration of sample-and-hold circuit including three capacitors

FIG. 5 is a circuit diagram illustrating an exemplary circuit configuration of sample-and-hold circuit 10 when sample-and-hold circuit 10 includes three capacitors.

As shown in FIG. 5, sample-and-hold circuit 10 includes first capacitor 11A, second capacitor 12A, third capacitor 13A, first buffer 21A, second buffer 22A, first input switch 31A, second input switch 32A, third input switch 33A, first output switch 41A, second output switch 42A, third output switch 43A, fourth output switch 44A, input 51, and output 52.

First capacitor 11A is a capacitor for holding pixel signals. First capacitor 11A is denoted by C1 in FIG. 5, the circuit diagrams and plan views to be described later, etc.

Second capacitor 12A is a capacitor for holding pixel signals and has a capacitance equal to a capacitance of first capacitor 11A. Second capacitor 12A is denoted by C2 in FIG. 5, the circuit diagrams and plan views to be described later, etc.

Third capacitor 13A is a capacitor for holding pixel signals and has a capacitance equal to the capacitance of first capacitor 11A. Third capacitor 13A is denoted by C3 in FIG. 5, the circuit diagrams and plan views to be described later, etc.

First buffer 21A is a buffer that has an output connected to output 52, that is, an output connected to AD conversion circuit 90 and is for buffering the pixel signals held by first capacitor 11A or the pixel signals held by second capacitor 12A. First buffer 21A is denoted by buf1 in FIG. 5, the circuit diagrams and plan views to be described later, etc.

Second buffer 22A is a buffer that has an output connected to output 52, that is, an output connected to AD conversion circuit 90 and is for buffering the pixel signals held by second capacitor 12A or the pixel signals held by third capacitor 13A. Second buffer 22A is denoted by buf2 in FIG. 5, the circuit diagrams and plan views to be described later, etc.

Here, it is assumed that first buffer 21A and second buffer 22A have the same characteristics.

First input switch 31A is a switch that is connected to input 51 and first capacitor 11A and alternates between the conductive state and the non-conductive state to connect or disconnect input 51 and first capacitor 11A. In other words, first input switch 31A is a switch that is disposed in an electrical path between vertical signal line 80 and first capacitor 11A, and alternates between the conductive state and the non-conductive state to connect or disconnect vertical signal line 80 and first capacitor 11A. First input switch 31A is denoted by SW11 in FIG. 5, the circuit diagrams and plan views to be described later, etc.

Second input switch 32A is a switch that is connected to input 51 and second capacitor 12A and alternates between the conductive state and the non-conductive state to connect or disconnect input 51 and second capacitor 12A. In other words, second input switch 32A is a switch that is disposed in an electrical path between vertical signal line 80 and second capacitor 12A, and alternates between the conductive state and the non-conductive state to connect or disconnect vertical signal line 80 and second capacitor 12A. Second input switch 32A is denoted by SW21 in FIG. 5, the circuit diagrams and plan views to be described later, etc.

Third input switch 33A is a switch that is connected to input 51 and third capacitor 13A and alternates between the conductive state and the non-conductive state to connect or disconnect input 51 and third capacitor 13A. In other words, third input switch 33A is a switch that is disposed in an electrical path between vertical signal line 80 and third capacitor 13A, and alternates between the conductive state and the non-conductive state to connect or disconnect vertical signal line 80 and third capacitor 13A. Third input switch 33A is denoted by SW31 in FIG. 5, the circuit diagrams and plan views to be described later, etc.

First output switch 41A is a switch that is connected to first capacitor 11A and an input of first buffer 21A and alternates between the conductive state and the non-conductive state to connect or disconnect first capacitor 11A and the input of first buffer 21A. In other words, first output switch 41A is a switch that is disposed in an electrical path between first capacitor 11A and the input of first buffer 21A, and alternates between the conductive state and the non-conductive state to connect or disconnect first capacitor 11A and the input of first buffer 21A. First output switch 41A is denoted by SW12 in FIG. 5, the circuit diagrams and plan views to be described later, etc.

Second output switch 42A is a switch that is connected to second capacitor 12A and the input of first buffer 21A and alternates between the conductive state and the non-conductive state to connect or disconnect second capacitor 12A and the input of first buffer 21A. In other words, second output switch 42A is a switch that is disposed in an electrical path between second capacitor 12A and the input of first buffer 21A, and alternates between the conductive state and the non-conductive state to connect or disconnect second capacitor 12A and the input of first buffer 21A. Second output switch 42A is denoted by SW22 in FIG. 5, the circuit diagrams and plan views to be described later, etc.

Third output switch 43A is a switch that is connected to second capacitor 12A and an input of second buffer 22A and alternates between the conductive state and the non-conductive state to connect or disconnect second capacitor 12A and the input of second buffer 22A. In other words, third output switch 43A is a switch that is disposed in an electrical path between second capacitor 12A and the input of second buffer 22A, and alternates between the conductive state and the non-conductive state to connect or disconnect second capacitor 12A and the input of second buffer 22A. Third output switch 43A is denoted by SW32 in FIG. 5, the circuit diagrams and plan views to be described later, etc.

Fourth output switch 44A is a switch that is connected to third capacitor 13A and the input of second buffer 22A and alternates between the conductive state and the non-conductive state to connect or disconnect third capacitor 13A and the input of second buffer 22A. In other words, fourth output switch 44A is a switch that is disposed in an electrical path between third capacitor 13A and the input of second buffer 22A, and alternates between the conductive state and the non-conductive state to connect or disconnect third capacitor 13A and the input of second buffer 22A. Fourth output switch 44A is denoted by SW42 in FIG. 5, the circuit diagrams and plan views to be described later, etc.

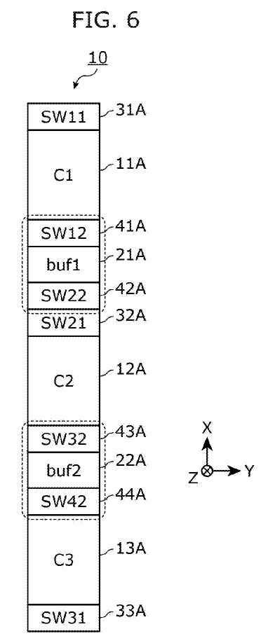

FIG. 6 is a plan-view schematic diagram illustrating an exemplary physical configuration of sample-and-hold circuit 10 shown in FIG. 5.

In FIG. 6, an X-axis direction is the column direction of pixel array 70, and a Y-axis direction is the row direction of pixel array 70. For this reason, FIG. 6 is a plan-view schematic diagram illustrating sample-and-hold circuit 10 in the plan view of pixel array 70.

As shown in FIG. 6, in the plan view of sample-and-hold circuit 10, that is, in the plan view of pixel array 70, first output switch 41A and first buffer 21A are adjacent to each other in the column direction (the X-axis direction in FIG. 6) of pixel array 70, second output switch 42A and first buffer 21A are adjacent to each other in the column direction of pixel array 70, third output switch 43A and second buffer 22A are adjacent to each other in the column direction of pixel array 70, and fourth output switch 44A and second buffer 22A are adjacent to each other in the column direction of pixel array 70.

Solid-state imaging device 1 including sample-and-hold circuit 10 thus configured makes it possible to minimize a parasitic capacitance in an electrical path between first output switch 41A and the input of first buffer 21A, a parasitic capacitance in an electrical path between second output switch 42A and the input of first buffer 21A, a parasitic capacitance in an electrical path between third output switch 43A and the input of second buffer 22A, and a parasitic capacitance in an electrical path between fourth output switch 44A and the input of second buffer 22A.

Moreover, solid-state imaging device 1 including sample-and-hold circuit 10 thus configured makes it possible to reduce relative variations among a parasitic capacitance in an electrical path between first input switch 31A and first output switch 41A, a parasitic capacitance in an electrical path between second input switch 32A and second output switch 42A, a parasitic capacitance in an electrical path between second input switch 32A and third output switch 43A, and a parasitic capacitance in an electrical path between third input switch 33A and fourth output switch 44A.

Furthermore, solid-state imaging device 1 including sample-and-hold circuit 10 thus configured includes sample-and-hold circuit 10 that includes first capacitor 11A, second capacitor 12A, and third capacitor 13A arranged in parallel to each other.

Accordingly, solid-state imaging device 1 including sample-and-hold circuit 10 thus configured makes it possible to achieve the higher captured image quality while achieving the high-speed imaging operation.

It should be noted that, as stated above, sample-and-hold circuit 10 may further include inputs of one or more buffers and one or more reset switches for resetting the plurality of capacitors.

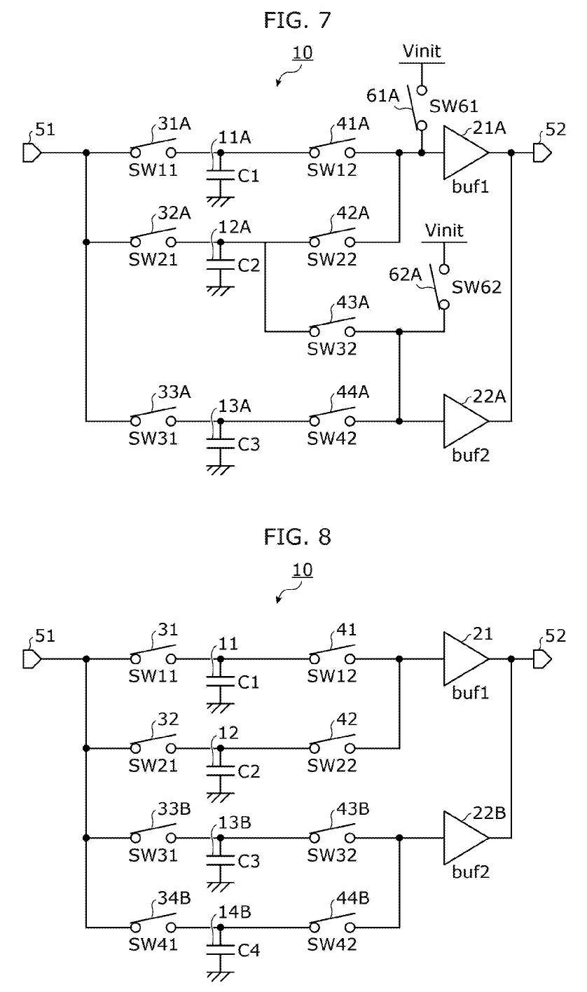

FIG. 7 is a circuit diagram illustrating an exemplary circuit configuration of sample-and-hold circuit 10 when sample-and-hold circuit 10 shown in FIG. 5 further includes first reset switch 61A for resetting the input of first buffer 21A to initialization voltage Vinit, and second reset switch 62A for resetting the input of second buffer 22A to initialization voltage Vinit.

First reset switch 61A is a switch that is connected to an output of an initialization power source that supplies initialization voltage Vinit and the input of first buffer 21A, and alternates between the conductive state and the non-conductive state to connect or disconnect the output of the initialization power source and the input of first buffer 21A. In other words, first reset switch 61A is a switch that is disposed in an electrical path between the output of the initialization power source and the input of first buffer 21A, and alternates between the conductive state and the non-conductive state to connect or disconnect the output of the initialization power source and the input of first buffer 21A. First reset switch 61A is denoted by SW61 in FIG. 7, the circuit diagrams and plan views to be described later, etc.

Second reset switch 62A is a switch that is connected to the output of the initialization power source that supplies initialization voltage Vinit and the input of second buffer 22A, and alternates between the conductive state and the non-conductive state to connect or disconnect the output of the initialization power source and the input of second buffer 22A. In other words, second reset switch 62A is a switch that is disposed in an electrical path between the output of the initialization power source and the input of second buffer 22A, and alternates between the conductive state and the non-conductive state to connect or disconnect the output of the initialization power source and the input of second buffer 22A. Second reset switch 62A is denoted by SW62 in FIG. 7, the circuit diagrams and plan views to be described later, etc.

By causing first reset switch 61A to be in the conductive state, solid-state imaging device 1 including sample-and-hold circuit 10 thus configured makes it possible to reset the input of first buffer 21A to initialization voltage Vinit.

In addition, by causing second reset switch 62A to be in the conductive state, solid-state imaging device 1 including sample-and-hold circuit 10 thus configured makes it possible to reset the input of second buffer 22A to initialization voltage Vinit.

Then, a configuration of sample-and-hold circuit 10 when sample-and-hold circuit 10 includes four capacitors is described.

### 1.2.C. Configuration of sample-and-hold circuit including four capacitors

FIG. 8 is a circuit diagram illustrating an exemplary circuit configuration of sample-and-hold circuit 10 when sample-and-hold circuit 10 includes four capacitors.

As shown in FIG. 8, sample-and-hold circuit 10 is configured by adding, to sample-and-hold circuit 10 including the two capacitors shown in FIG. 2, third capacitor 13B, fourth capacitor 14B, second buffer 22B, third input switch 33B, fourth input switch 34B, third output switch 43B, and fourth output switch 44B.

Third capacitor 13B is a capacitor for holding pixel signals and has a capacitance equal to a capacitance of first capacitor 11. Third capacitor 13B is denoted by C3 in FIG. 8, the circuit diagrams and plan views to be described later, etc.

Fourth capacitor 14B is a capacitor for holding pixel signals and has a capacitance equal to the capacitance of first capacitor 11. Fourth capacitor 14B is denoted by C4 in FIG. 8, the circuit diagrams and plan views to be described later, etc.

Second buffer 22B is a buffer that has an output connected to output 52, that is, an output connected to AD conversion circuit 90 and is for buffering the pixel signals held by third capacitor 13B or the pixel signals held by fourth capacitor 14B. Second buffer 22B is denoted by buf2 in FIG. 8, the circuit diagrams and plan views to be described later, etc.

Here, it is assumed that first buffer 21 and second buffer 22B have the same characteristics.

Third input switch 33B is a switch that is connected to input 51 and third capacitor 13B and alternates between the conductive state and the non-conductive state to connect or disconnect input 51 and third capacitor 13B. In other words, third input switch 33B is a switch that is disposed in an electrical path between vertical signal line 80 and third capacitor 13B, and alternates between the conductive state and the non-conductive state to connect or disconnect vertical signal line 80 and third capacitor 13B. Third input switch 33B is denoted by SW31 in FIG. 8, the circuit diagrams and plan views to be described later, etc.

Fourth input switch 34B is a switch that is connected to input 51 and fourth capacitor 14B and alternates between the conductive state and the non-conductive state to connect or disconnect input 51 and fourth capacitor 14B. In other words, fourth input switch 34B is a switch that is disposed in an electrical path between vertical signal line 80 and fourth capacitor 14B, and alternates between the conductive state and the non-conductive state to connect or disconnect vertical signal line 80 and fourth capacitor 14B. Fourth input switch 34B is denoted by SW41 in FIG. 8, the circuit diagrams and plan views to be described later, etc.

Third output switch 43B is a switch that is connected to third capacitor 13B and an input of second buffer 22B and alternates between the conductive state and the non-conductive state to connect or disconnect third capacitor 13B and the input of second buffer 22B. In other words, third output switch 43B is a switch that is disposed in an electrical path between third capacitor 13B and the input of second buffer 22B, and alternates between the conductive state and the non-conductive state to connect or disconnect third capacitor 13B and the input of second buffer 22B. Third output switch 43B is denoted by SW32 in FIG. 8, the circuit diagrams and plan views to be described later, etc.

Fourth output switch 44B is a switch that is connected to fourth capacitor 14B and the input of second buffer 22B and alternates between the conductive state and the non-conductive state to connect or disconnect fourth capacitor 14B and the input of second buffer 22B. In other words, fourth output switch 44B is a switch that is disposed in an electrical path between fourth capacitor 14B and the input of second buffer 22B, and alternates between the conductive state and the non-conductive state to connect or disconnect fourth capacitor 14B and the input of second buffer 22B. Fourth output switch 44B is denoted by SW42 in FIG. 8, the circuit diagrams and plan views to be described later, etc.

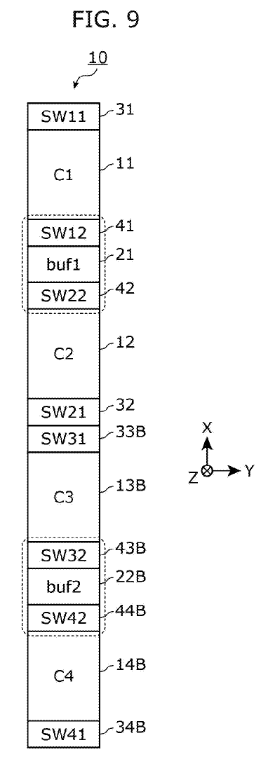

FIG. 9 is a plan-view schematic diagram illustrating an exemplary physical configuration of sample-and-hold circuit 10 when sample-and-hold circuit 10 includes the four capacitors.

In FIG. 9, an X-axis direction is the column direction of pixel array 70, and a Y-axis direction is the row direction of pixel array 70. For this reason, FIG. 9 is a plan-view schematic diagram illustrating sample-and-hold circuit 10 in the plan view of pixel array 70.

As shown in FIG. 9, in the plan view of sample-and-hold circuit 10, that is, in the plan view of pixel array 70, first output switch 41 and first buffer 21 are adjacent to each other in the column direction (the X-axis direction in FIG. 9) of pixel array 70, second output switch 42 and first buffer 21 are adjacent to each other in the column direction of pixel array 70, third output switch 43B and second buffer 22B are adjacent to each other in the column direction of pixel array 70, and fourth output switch 44B and second buffer 22B are adjacent to each other in the column direction of pixel array 70.

Solid-state imaging device 1 including sample-and-hold circuit 10 thus configured makes it possible to minimize a parasitic capacitance in an electrical path between first output switch 41 and the input of first buffer 21, a parasitic capacitance in an electrical path between second output switch 42 and the input of first buffer 21, a parasitic capacitance in an electrical path between third output switch 43B and the input of second buffer 22B, and a parasitic capacitance in an electrical path between fourth output switch 44B and the input of second buffer 22B.

Moreover, solid-state imaging device 1 including sample-and-hold circuit 10 thus configured makes it possible to reduce relative variations among a parasitic capacitance in an electrical path between first input switch 31 and first output switch 41, a parasitic capacitance in an electrical path between second input switch 32 and second output switch 42, a parasitic capacitance in an electrical path between third input switch 33B and third output switch 43B, and a parasitic capacitance in an electrical path between fourth input switch 34B and fourth output switch 44B.

Furthermore, solid-state imaging device 1 including sample-and-hold circuit 10 thus configured includes sample-and-hold circuit 10 that includes first capacitor 11, second capacitor 12, third capacitor 13B, and fourth capacitor 14B arranged in parallel to each other.

Accordingly, solid-state imaging device 1 including sample-and-hold circuit 10 thus configured makes it possible to achieve the higher captured image quality while achieving the high-speed imaging operation.

It should be noted that, as stated above, sample-and-hold circuit 10 may further include inputs of one or more buffers and one or more reset switches for resetting the plurality of capacitors.

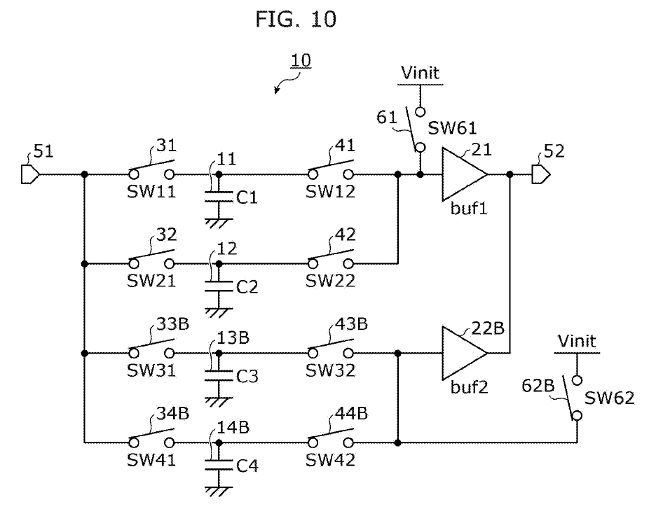

FIG. 10 is a circuit diagram illustrating an exemplary circuit configuration of sample-and-hold circuit 10 when sample-and-hold circuit 10 shown in FIG. 8 further includes first reset switch 61 for resetting the input of first buffer 21 to initialization voltage Vinit, and second reset switch 62B for resetting the input of second buffer 22B to initialization voltage Vinit.

Second reset switch 62B is a switch that is connected to an output of an initialization power source that supplies initialization voltage Vinit and the input of second buffer 22B, and alternates between the conductive state and the non-conductive state to connect or disconnect the output of the initialization power source and the input of second buffer 22B. In other words, second reset switch 62B is a switch that is disposed in an electrical path between the output of the initialization power source and the input of second buffer 22B, and alternates between the conductive state and the non-conductive state to connect or disconnect the output of the initialization power source and the input of second buffer 22B. Second reset switch 62B is denoted by SW62 in FIG. 10.

By causing first reset switch 61 to be in the conductive state, solid-state imaging device 1 including sample-and-hold circuit 10 thus configured makes it possible to reset the input of first buffer 21 to initialization voltage Vinit.

Next, a configuration of sample-and-hold circuit 10 when sample-and-hold circuit 10 includes five capacitors is described.

### 1.2.D. Configuration of sample-and-hold circuit including five capacitors

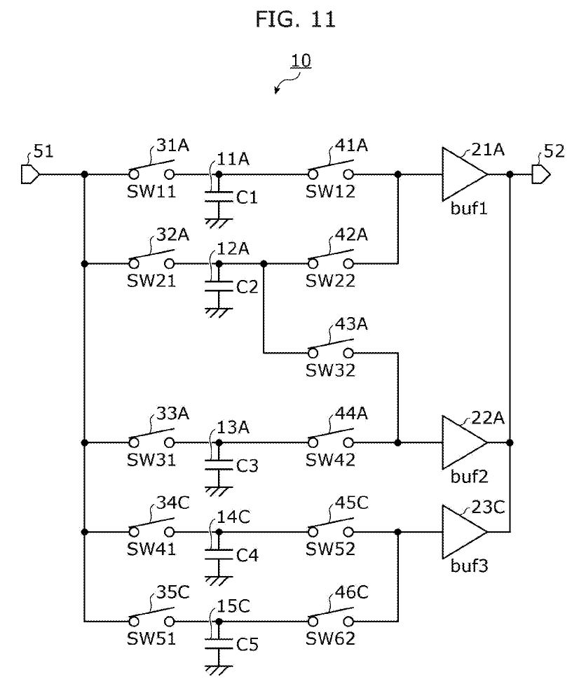

FIG. 11 is a circuit diagram illustrating an exemplary circuit configuration of sample-and-hold circuit 10 when sample-and-hold circuit 10 includes five capacitors.

As shown in FIG. 11, sample-and-hold circuit 10 is configured by adding, to sample-and-hold circuit 10 including the three capacitors shown in FIG. 5, fourth capacitor 14C, fifth capacitor 15C, third buffer 23C, fourth input switch 34C, fifth input switch 35C, fifth output switch 45C, and sixth output switch 46C.

Fourth capacitor 14C is a capacitor for holding pixel signals and has a capacitance equal to a capacitance of first capacitor 11A. Fourth capacitor 14C is denoted by C4 in FIG. 11, the circuit diagrams and plan views to be described later, etc.

Fifth capacitor 15C is a capacitor for holding pixel signals and has a capacitance equal to the capacitance of first capacitor 11A. Fifth capacitor 15C is denoted by C5 in FIG. 11, the circuit diagrams and plan views to be described later, etc.

Third buffer 23C is a buffer that has an output connected to output 52, that is, an output connected to AD conversion circuit 90 and is for buffering the pixel signals held by fourth capacitor 14C or the pixel signals held by fifth capacitor 15C. Third buffer 23C is denoted by buf3 in FIG. 11, the circuit diagrams and plan views to be described later, etc.

Here, it is assumed that first buffer 21A, second buffer 22A, and third buffer 23C have the same characteristics.

Fourth input switch 34C is a switch that is connected to input 51 and fourth capacitor 14C and alternates between the conductive state and the non-conductive state to connect or disconnect input 51 and fourth capacitor 14C. In other words, fourth input switch 34C is a switch that is disposed in an electrical path between vertical signal line 80 and fourth capacitor 14C, and alternates between the conductive state and the non-conductive state to connect or disconnect vertical signal line 80 and fourth capacitor 14C. Fourth input switch 34C is denoted by SW41 in FIG. 11, the circuit diagrams and plan views to be described later, etc.

Fifth input switch 35C is a switch that is connected to input 51 and fifth capacitor 15C and alternates between the conductive state and the non-conductive state to connect or disconnect input 51 and fifth capacitor 15C. In other words, fifth input switch 35C is a switch that is disposed in an electrical path between vertical signal line 80 and fifth capacitor 15C, and alternates between the conductive state and the non-conductive state to connect or disconnect vertical signal line 80 and fifth capacitor 15C. Fifth input switch 35C is denoted by SW51 in FIG. 11, the circuit diagrams and plan views to be described later, etc.

Fifth output switch 45C is a switch that is connected to fourth capacitor 14C and an input of third buffer 23C and alternates between the conductive state and the non-conductive state to connect or disconnect fourth capacitor 14C and the input of third buffer 23C. In other words, fifth output switch 45C is a switch that is disposed in an electrical path between fourth capacitor 14C and the input of third buffer 23C, and alternates between the conductive state and the non-conductive state to connect or disconnect fourth capacitor 14C and the input of third buffer 23C. Fifth output switch 45C is denoted by SW52 in FIG. 11, the circuit diagrams and plan views to be described later, etc.

Sixth output switch 46C is a switch that is connected to fifth capacitor 15C and the input of third buffer 23C and alternates between the conductive state and the non-conductive state to connect or disconnect fifth capacitor 15C and the input of third buffer 23C. In other words, sixth output switch 46C is a switch that is disposed in an electrical path between fifth capacitor 15C and the input of third buffer 23C, and alternates between the conductive state and the non-conductive state to connect or disconnect fifth capacitor 15C and the input of third buffer 23C. Sixth output switch 46C is denoted by SW62 in FIG. 11, the circuit diagrams and plan views to be described later, etc.

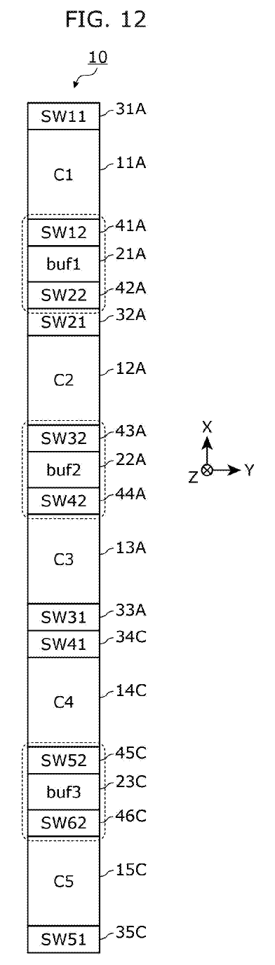

FIG. 12 is a plan-view schematic diagram illustrating an exemplary physical configuration of sample-and-hold circuit 10 shown in FIG. 11.

In FIG. 12, an X-axis direction is the column direction of pixel array 70, and a Y-axis direction is the row direction of pixel array 70. For this reason, FIG. 12 is a plan-view schematic diagram illustrating sample-and-hold circuit 10 in the plan view of pixel array 70.

As shown in FIG. 12, in the plan view of sample-and-hold circuit 10, that is, in the plan view of pixel array 70, first output switch 41A and first buffer 21A are adjacent to each other in the column direction (the X-axis direction in FIG. 12) of pixel array 70, second output switch 42A and first buffer 21A are adjacent to each other in the column direction of pixel array 70, third output switch 43A and second buffer 22A are adjacent to each other in the column direction of pixel array 70, fourth output switch 44A and second buffer 22A are adjacent to each other in the column direction of pixel array 70, fifth output switch 45C and third buffer 23C are adjacent to each other in the column direction of pixel array 70, and sixth output switch 46C and third buffer 23C are adjacent to each other in the column direction of pixel array 70.

Solid-state imaging device 1 including sample-and-hold circuit 10 thus configured makes it possible to minimize a parasitic capacitance in an electrical path between first output switch 41A and the input of first buffer 21A, a parasitic capacitance in an electrical path between second output switch 42A and the input of first buffer 21A, a parasitic capacitance in an electrical path between third output switch 43A and the input of second buffer 22A, a parasitic capacitance in an electrical path between fourth output switch 44A and the input of second buffer 22A, a parasitic capacitance in an electrical path between fifth output switch 45C and the input of third buffer 23C, and a parasitic capacitance in an electrical path between sixth output switch 46C and the input of third buffer 23C.

Moreover, solid-state imaging device 1 including sample-and-hold circuit 10 thus configured makes it possible to reduce relative variations among a parasitic capacitance in an electrical path between first input switch 31A and first output switch 41A, a parasitic capacitance in an electrical path between second input switch 32A and second output switch 42A, a parasitic capacitance in an electrical path between second input switch 32A and third output switch 43A, a parasitic capacitance in an electrical path between third input switch 33A and fourth output switch 44A, a parasitic capacitance in an electrical path between fourth input switch 34C and fifth output switch 45C, and a parasitic capacitance in an electrical path between fifth input switch 35C and sixth output switch 46C.

Furthermore, solid-state imaging device 1 including sample-and-hold circuit 10 thus configured includes sample-and-hold circuit 10 that includes first capacitor 11A, second capacitor 12A, third capacitor 13A, fourth capacitor 14C, and fifth capacitor 15C arranged in parallel to each other.

Accordingly, solid-state imaging device 1 including sample-and-hold circuit 10 thus configured makes it possible to achieve the higher captured image quality while achieving the high-speed imaging operation.

It should be noted that, as stated above, sample-and-hold circuit 10 may further include inputs of one or more buffers and one or more reset switches for resetting the plurality of capacitors.

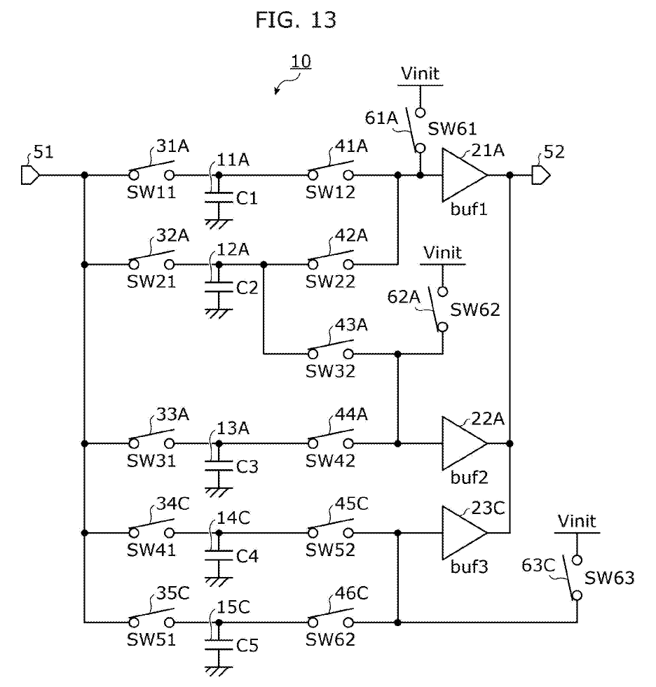

FIG. 13 is a circuit diagram illustrating an exemplary circuit configuration of sample-and-hold circuit 10 when sample-and-hold circuit 10 shown in FIG. 11 further includes first reset switch 61A for resetting the input of first buffer 21A to initialization voltage Vinit, second reset switch 62A for resetting the input of second buffer 22A to initialization voltage Vinit, and third reset switch 63C for resetting the input of third buffer 23C to initialization voltage Vinit.

Third reset switch 63C is a switch that is connected to an output of an initialization power source that supplies initialization voltage Vinit and the input of third buffer 23C, and alternates between the conductive state and the non-conductive state to connect or disconnect the output of the initialization power source and the input of third buffer 23C. In other words, third reset switch 63C is a switch that is disposed in an electrical path between the output of the initialization power source and the input of third buffer 23C, and alternates between the conductive state and the non-conductive state to connect or disconnect the output of the initialization power source and the input of third buffer 23C. Third reset switch 63C is denoted by SW63 in FIG. 13.

By causing first reset switch 61A to be in the conductive state, solid-state imaging device 1 including sample-and-hold circuit 10 thus configured makes it possible to reset the input of first buffer 21A to initialization voltage Vinit.

In addition, by causing second reset switch 62A to be in the conductive state, solid-state imaging device 1 including sample-and-hold circuit 10 thus configured makes it possible to reset the input of second buffer 22A to initialization voltage Vinit.

Additionally, by causing third reset switch 63C to be in the conductive state, solid-state imaging device 1 including sample-and-hold circuit 10 thus configured makes it possible to reset the input of third buffer 23C to initialization voltage Vinit.

### 1.2.E. Configuration of sample-and-hold circuit including 4 + 2k (k is an integer greater than or equal to 1) capacitors

Sample-and-hold circuit 10 including 4 + 2k capacitors is achieved by further providing k circuit groups in parallel, for example, in sample-and-hold circuit 10 shown in FIG. 8, the k circuit groups each including third capacitor 13B, fourth capacitor 14B, second buffer 22B, third input switch 33B, fourth input switch 34B, third output switch 43B, and fourth output switch 44B.

At this time, in each of the k circuit groups further provided, the relative positional relationship shown in FIG. 9 is maintained for a relative positional relationship among third capacitor 13B, fourth capacitor 14B, second buffer 22B, third input switch 33B, fourth input switch 34B, third output switch 43B, and fourth output switch 44B included in the circuit group.

In addition, sample-and-hold circuit 10 including 4 + 2k capacitors is achieved by further providing k circuit groups in parallel, for example, in sample-and-hold circuit 10 shown in FIG. 10, the k circuit groups each including third capacitor 13B, fourth capacitor 14B, second buffer 22B, third input switch 33B, fourth input switch 34B, third output switch 43B, fourth output switch 44B, and second reset switch 62B.

At this time, in each of the k circuit groups further provided, the relative positional relationship shown in FIG. 9 is maintained for a relative positional relationship among third capacitor 13B, fourth capacitor 14B, second buffer 22B, third input switch 33B, fourth input switch 34B, third output switch 43B, and fourth output switch 44B included in the circuit group.

### 1.2.F. Configuration of sample-and-hold circuit including 5 + 2k (k is an integer greater than or equal to 1) capacitors

Sample-and-hold circuit 10 including 5 + 2k capacitors is achieved by further providing k circuit groups in parallel, for example, in sample-and-hold circuit 10 shown in FIG. 11, the k circuit groups each including fourth capacitor 14C, fifth capacitor 15C, third buffer 23C, fourth input switch 34C, fifth input switch 35C, fifth output switch 45C, and sixth output switch 46C.

At this time, in each of the k circuit groups further provided, the relative positional relationship shown in FIG. 12 is maintained for a relative positional relationship among fourth capacitor 14C, fifth capacitor 15C, third buffer 23C, fourth input switch 34C, fifth input switch 35C, fifth output switch 45C, and sixth output switch 46C included in the circuit group.

In addition, sample-and-hold circuit 10 including 5 + 2k capacitors is achieved by further providing k circuit groups in parallel, for example, in sample-and-hold circuit 10 shown in FIG. 13, the k circuit groups each including fourth capacitor 14C, fifth capacitor 15C, third buffer 23C, fourth input switch 34C, fifth input switch 35C, fifth output switch 45C, sixth output switch 46C, and third reset switch 63C.

At this time, in each of the k circuit groups further provided, the relative positional relationship shown in FIG. 12 is maintained for a relative positional relationship among fourth capacitor 14C, fifth capacitor 15C, third buffer 23C, fourth input switch 34C, fifth input switch 35C, fifth output switch 45C, and sixth output switch 46C included in the circuit group.

### 1.3. Operation of solid-state imaging device

Hereinafter, the operation of solid-state imaging device 1 thus configured is described.

Here, the following illustrates, as an example, solid-state imaging device 1 when sample-and-hold circuit 10 included in solid-state imaging device 1 is configured to include the three capacitors and the two reset switches shown in FIG. 7.

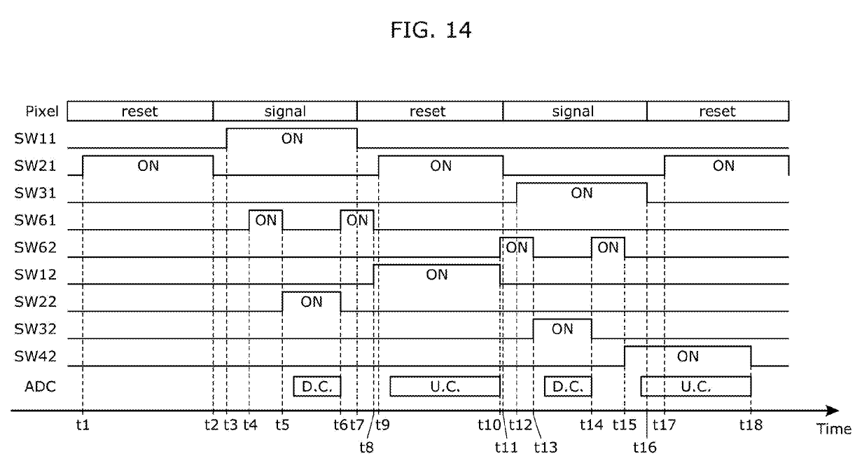

FIG. 14 is a timing chart for first readout pipeline control processing performed by solid-state imaging device 1.

The first readout pipeline control processing is processing for reading out a pixel signal from pixel 3 in a reset state and a pixel signal from pixel 3 in an exposure state via pipeline control, to perform digital correlated double sampling.

Hereinafter, a pixel signal of pixel 3 in the reset state is also referred to as a reset level or a dark level, and a pixel signal of pixel 3 in the exposure state is also referred to as a signal level.

In FIG. 14, SW11 denotes a control signal for first input switch 31A and denotes a control signal for connecting vertical signal line 80 and first capacitor 11A at a high logic level and disconnecting vertical signal line 80 and first capacitor 11A at a low logic level.

SW21 denotes a control signal for second input switch 32A and denotes a control signal for connecting vertical signal line 80 and second capacitor 12A at the high logic level and disconnecting vertical signal line 80 and second capacitor 12A at the low logic level.

SW31 denotes a control signal for third input switch 33A and denotes a control signal for connecting vertical signal line 80 and third capacitor 13A at the high logic level and disconnecting vertical signal line 80 and third capacitor 13A at the low logic level.

SW61 denotes a control signal for first reset switch 61A and denotes a control signal for connecting the output of the initialization power source and the input of first buffer 21A at the high logic level and disconnecting the output of the initialization power source and the input of first buffer 21A at the low logic level.

SW62 denotes a control signal for second reset switch 62A and denotes a control signal for connecting the output of the initialization power source and the input of second buffer 22A at the high logic level and disconnecting the output of the initialization power source and the input of second buffer 22A at the low logic level.

SW12 denotes a control signal for first output switch 41A and denotes a control signal for connecting first capacitor 11A and the input of first buffer 21A at the high logic level and disconnecting first capacitor 11A and the input of first buffer 21A at the low logic level.

SW22 denotes a control signal for second output switch 42A and denotes a control signal for connecting second capacitor 12A and the input of first buffer 21A at the high logic level and disconnecting second capacitor 12A and the input of first buffer 21A at the low logic level.

SW32 denotes a control signal for third output switch 43A and denotes a control signal for connecting second capacitor 12A and the input of second buffer 22A at the high logic level and disconnecting second capacitor 12A and the input of second buffer 22A at the low logic level.

SW42 denotes a control signal for fourth output switch 44A and denotes a control signal for connecting third capacitor 13A and the input of second buffer 22A at the high logic level and disconnecting third capacitor 13A and the input of second buffer 22A at the low logic level.

ADC denotes an operation performed by AD conversion circuit 90, D.C. (DownCount) denotes a dark level readout operation, and U.C. (UpCount) denotes a signal level readout operation.

As shown in FIG. 14, at time t1, by setting control signal SW21 to the high logic level, solid-state imaging device 1 causes second capacitor 12A to obtain a dark level of pixel 3 (the first time). A high logic level period of control signal SW21 continues until time t2.

Next, at time t3, by setting control signal SW11 to the high logic level, solid-state imaging device 1 causes first capacitor 11A to obtain a signal level of pixel 3 (the first time). A high logic level period of control signal SW11 continues until time t7.

Then, at time t4, by setting control signal SW61 to the high logic level, solid-state imaging device 1 resets the input of first buffer 21A to initialization voltage Vinit. A high logic level period of control signal SW61 continues until time t5.

After that, at time t5, by setting control signal SW22 to the high logic level, solid-state imaging device 1 outputs the dark level of pixel 3 obtained and held by second capacitor 12A to the input of first buffer 21A. In that case, first buffer 21A outputs, to AD conversion circuit 90, a signal corresponding to the dark level obtained and held by second capacitor 12A. Under those circumstances, AD conversion circuit 90 performs AD conversion on the signal outputted from first buffer 21A, that is, AD conversion circuit 90 reads out the dark level of pixel 3 (the first time). A high logic level period of control signal SW22 continues until time t6.

Next, at time t6, by setting control signal SW61 to the high logic level, solid-state imaging device 1 resets the input of first buffer 21A to initialization voltage Vinit. A high logic level period of control signal SW61 continues until time t8.

Then, at time t8, by setting control signal SW12 to the high logic level, solid-state imaging device 1 outputs the signal level of pixel 3 obtained and held by first capacitor 11A to the input of first buffer 21A. In that case, first buffer 21A outputs, to AD conversion circuit 90, a signal corresponding to the signal level obtained and held by first capacitor 11A. Under those circumstances, AD conversion circuit 90 performs AD conversion on the signal outputted from first buffer 21A, that is, AD conversion circuit 90 reads out the signal level of pixel 3 (the first time). A high logic level period of control signal SW12 continues until time t10.

After that, at time t9, by setting control signal SW21 to the high logic level, solid-state imaging device 1 causes second capacitor 12A to obtain a dark level of pixel 3 (the second time). A high logic level period of control signal SW21 continues until time t11.

Next, at time t10, by setting control signal SW62 to the high logic level, solid-state imaging device 1 resets the input of second buffer 22A to initialization voltage Vinit. A high logic level period of control signal SW62 continues until time t13.

Then, at time t12, by setting control signal SW31 to the high logic level, solid-state imaging device 1 causes third capacitor 13A to obtain a signal level of pixel 3 (the second time). A high logic level period of control signal SW31 continues until time t16.

After that, at time t13, by setting control signal SW32 to the high logic level, solid-state imaging device 1 outputs the dark level of pixel 3 obtained and held by second capacitor 12A to the input of second buffer 22A. In that case, second buffer 22A outputs, to AD conversion circuit 90, a signal corresponding to the dark level obtained and held by second capacitor 12A. Under those circumstances, AD conversion circuit 90 performs AD conversion on the signal outputted from second buffer 22A, that is, AD conversion circuit 90 reads out the dark level of pixel 3 (the second time). A high logic level period of control signal SW32 continues until time t14.

Next, at time t14, by setting control signal SW62 to the high logic level, solid-state imaging device 1 resets the input of second buffer 22A to initialization voltage Vinit. A high logic level period of control signal SW62 continues until time t15.

Then, at time t15, by setting control signal SW42 to the high logic level, solid-state imaging device 1 outputs the signal level of pixel 3 obtained and held by third capacitor 13A to the input of second buffer 22A. In that case, second buffer 22A outputs, to AD conversion circuit 90, a signal corresponding to the signal level obtained and held by third capacitor 13A. Under those circumstances, AD conversion circuit 90 performs AD conversion on the signal outputted from second buffer 22A, that is, AD conversion circuit 90 reads out the signal level of pixel 3 (the second time). A high logic level period of control signal SW42 continues until time t18.

As shown in FIG. 14, control signals SW11, SW21, and SW31 do not transition to the high logic level at the same time.

Moreover, immediately before control signal SW12 transitions to the high logic level and immediately before control signal SW22 transitions to the high logic level, the input of first buffer 21A is reset to initialization voltage Vinit.

Furthermore, while the input of first buffer 21A is reset to initialization voltage Vinit, neither control signal SW12 nor control signal SW22 transitions to the high logic level.

Moreover, immediately before control signals SW32 and SW42 transition to the high logic level, the input of second buffer 22A is reset to initialization voltage Vinit.

Furthermore, while the input of second buffer 22A is reset to initialization voltage Vinit, neither control signal SW32 nor control signal SW42 transitions to the high logic level.

With regard to the readout of the dark level of pixel 3 and the readout of the signal level of pixel 3, (1) readout of a dark level via second capacitor 12A and first buffer 21A and readout of a signal level via first capacitor 11A and first buffer 21A and (2) readout of a dark level via second capacitor 12A and second buffer 22A and readout of a signal level via third capacitor 13A and second buffer 22A are alternately repeated.

### Variation 1

The following describes a solid-state imaging device according to Variation 1 configured by replacing sample-and-hold circuit 10 of solid-state imaging device 1 according to Embodiment 1 with a sample-and-hold circuit according to Variation 1.

Here, the sample-and-hold circuit according to Variation 1 is configured by adding a fixed voltage output circuit and one or more reset switches (corresponding to first buffer 21, first buffer 21A, second buffer 22A, second buffer 22B, and third buffer 23C in Embodiment 1) to sample-and-hold circuit 10 according to Embodiment 1, the fixed voltage output circuit outputting, to the one or more buffers, an operating voltage for causing the one or more buffers to operate, the one or more reset switches being each disposed in an electrical path between an output of the fixed voltage output circuit and a corresponding one of inputs of the one or more buffers, the operating voltage having a fixed electric potential.

Here, the following illustrates, as an example, the solid-state imaging device according to Variation 1 when the sample-and-hold circuit according to Variation 1 is configured to include two capacitors and one reset switch.

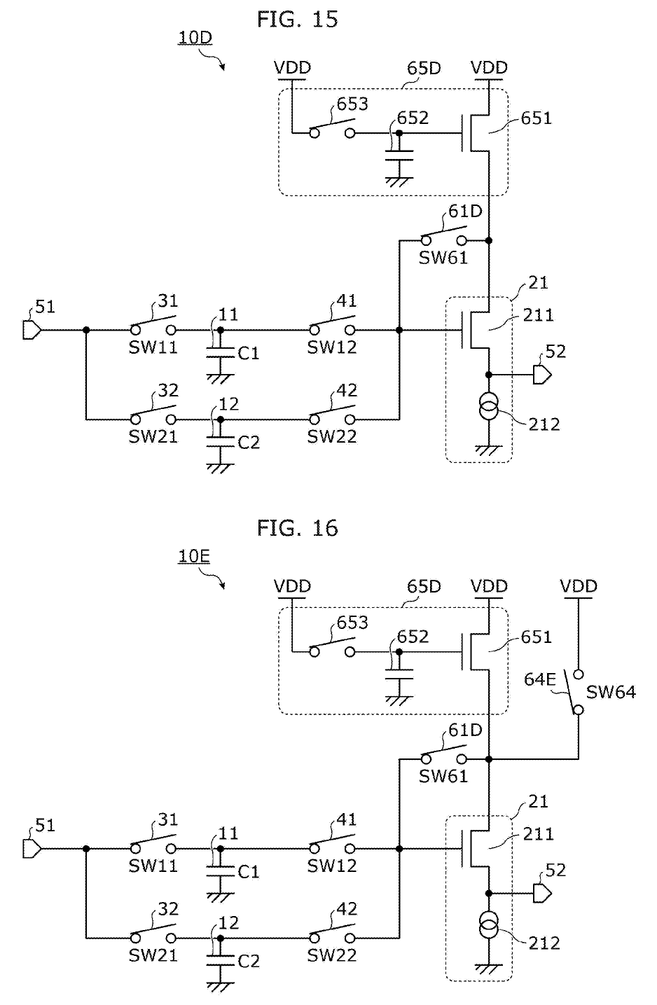

FIG. 15 is a circuit diagram illustrating an exemplary circuit configuration of sample-and-hold circuit 10D according to Variation 1 included in the solid-state imaging device according to Variation 1.

As shown in FIG. 15, sample-and-hold circuit 10D is configured by adding fixed voltage output circuit 65D and first reset switch 61D to sample-and-hold circuit 10 shown in FIG. 2.

In addition, as an exemplary circuit configuration of first buffer 21, first buffer 21 is illustrated as including constant current source 212 and source follower transistor 211.

Fixed voltage output circuit 65D outputs, to one or more buffers (here, first buffer 21) included in sample-and-hold circuit 10D, an operating voltage for causing the one or more buffers (here, first buffer 21) to operate, the operating voltage having a fixed electric potential.

As shown in FIG. 15, as an example, fixed voltage output circuit 65D includes transistor 651, electric-potential-holding capacitor 652, and electric-potential-holding switch 653.

Here, the following description assumes that transistor 651 is an n-channel transistor. However, transistor 651 need not be limited to the n-channel transistor and may be a p-channel transistor.

Transistor 651 has a drain connected to a power supply line of the solid-state imaging device according to Variation 1, and a source connected to an output of fixed voltage output circuit 65D.

Here, the following description assumes that a threshold voltage of transistor 651 is denoted by Vth.

Electric-potential-holding capacitor 652 is connected to a gate of transistor 651.

Electric-potential-holding switch 653 is a switch that is connected to the power supply line of the solid-state imaging device according to Variation 1 and electric-potential-holding capacitor 652, and alternates between the conductive state and the non-conductive state to connect or disconnect the power supply line of the solid-state imaging device according to Variation 1 and electric-potential-holding capacitor 652. In other words, electric-potential-holding switch 653 is a switch that is disposed in an electrical path between the power supply line of the solid-state imaging device according to Variation 1 and electric-potential-holding capacitor 652, and alternates between the conductive state and the non-conductive state to connect or disconnect the power supply line of the solid-state imaging device according to Variation 1 and electric-potential-holding capacitor 652.

First reset switch 61D is a switch that is connected to the output of fixed voltage output circuit 65D and an input of first buffer 21, and alternates between the conductive state and the non-conductive state to connect or disconnect the output of fixed voltage output circuit 65D and the input of first buffer 21. In other words, first reset switch 61D is a switch that is disposed in an electrical path between the output of fixed voltage output circuit 65D and the input of first buffer 21, and alternates between the conductive state and the non-conductive state to connect or disconnect the output of fixed voltage output circuit 65D and the input of first buffer 21. First reset switch 61D is denoted by SW61 in FIG. 15, the circuit diagrams and plan views to be described later, etc.

The solid-state imaging device according to Variation 1 thus configured makes it possible to stabilize an electric potential of the gate of transistor 651 constantly at VDD by (i) causing electric-potential-holding switch 653 to be in the conductive state during a period in which an electric potential of the power supply line of the solid-state imaging device according to Variation 1 is stable at VDD, for example, a period except for a period in which the solid-state imaging device according to Variation 1 reads out pixel signals from pixels 3, and (ii) causing electric-potential-holding switch 653 to be in the non-conductive state during a period in which an electric potential of the power supply line of the solid-state imaging device according to Variation 1 is not stable at VDD, for example, a period in which the solid-state imaging device according to Variation 1 reads out pixel signals from pixels 3.

Accordingly, fixed voltage output circuit 65D outputs a VDD – Vth operating voltage that is a fixed electric potential to the one or more buffers (here, first buffer 21).

Since the operating voltage of the one or more buffers (here, first buffer 21) included in sample-and-hold circuit 10D becomes VDD – Vth that is the fixed electric potential independent of variations in power supply voltage, the solid-state imaging device according to Variation 1 including sample-and-hold circuit 10D thus configured makes it possible to further stabilize the operation of the one or more buffers (here, first buffer 21).

As a result, it is possible to reset the one or more buffers (here, first buffer 21) stably to VDD – Vth that is the fixed electric potential.

Accordingly, the solid-state imaging device according to Variation 1 including sample-and-hold circuit 10D thus configured makes it possible to achieve significantly higher captured image quality.

### Variation 2

The following describes a solid-state imaging device according to Variation 2 configured by replacing sample-and-hold circuit 10D of the solid-state imaging device according to Variation 1 with a sample-and-hold circuit according to Variation 2.

Here, the sample-and-hold circuit according to Variation 2 is configured by adding, to sample-and-hold circuit 10D according to Variation 1, a pull-up switch that pulls up the output of fixed voltage output circuit 65D.

Here, the following description illustrates, as an example, the solid-state imaging device according to Variation 2 when the sample-and-hold circuit according to Variation 2 is configured to include two capacitors and one reset switch.

FIG. 16 is a circuit diagram illustrating an exemplary circuit configuration of sample-and-hold circuit 10E according to Variation 2 included in the solid-state imaging device according to Variation 2.

As shown in FIG. 16, sample-and-hold circuit 10E is configured by adding pull-up switch 64E to sample-and-hold circuit 10D shown in FIG. 15.

Pull-up switch 64E is a switch that pulls up the output of fixed voltage output circuit 65D, and is a switch that is connected to a power supply line of the solid-state imaging device according to Variation 2 and the output of fixed voltage output circuit 65D, and alternates between the conductive state and the non-conductive state to connect or disconnect the power supply line of solid-state imaging device according to Variation 2 and the output of fixed voltage output circuit 65D. In other words, pull-up switch 64E is a switch that is disposed in an electrical path between the power supply line of the solid-state imaging device according to Variation 2 and the output of fixed voltage output circuit 65D, and alternates between the conductive state and the non-conductive state to connect or disconnect the power supply line of the solid-state imaging device according to Variation 2 and the output of fixed voltage output circuit 65D. Pull-up switch 64E is denoted by SW64 in FIG. 16, the circuit diagrams and plan views to be described later, etc.

Since the solid-state imaging device according to Variation 2 thus configured allows one or more buffers (here, first buffer 21) included in sample-and-hold circuit 10E to operate at an electric potential pulled up from VDD − Vth to VDD, by causing pull-up switch 64E to be in the conductive state during a period in which the one or more buffers operate, the solid-state imaging device makes it possible to expand a dynamic range of each buffer (here, first buffer 21).

For this reason, it is possible to improve the linearity of each buffer (here, first buffer 21).

Accordingly, the solid-state imaging device according to Variation 2 including sample-and-hold circuit 10E thus configured makes it possible to achieve significantly higher captured image quality.

It should be noted that although the above description assumes that pull-up switch 64E is the switch that pulls up the output of fixed voltage output circuit 65D, pull-up switch 64E need not be limited to the switch that pulls up the output of fixed voltage output circuit 65D and may be a switch that pulls down the output of fixed voltage output circuit 65D.

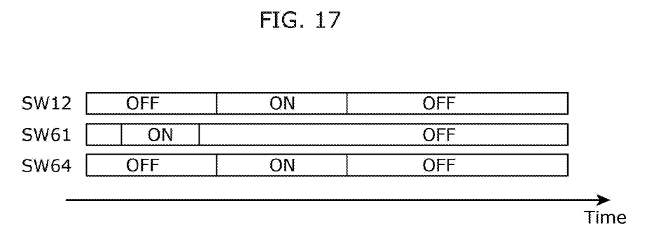

FIG. 17 is a timing chart for exemplary operations performed by the solid-state imaging device according to Variation 2.

In FIG. 17, SW12 shows a state of first output switch 41. To put it another way, a period in which SW12 is “ON” indicates that first output switch 41 is in the conductive state, and a period in which SW12 is “OFF” indicates that first output switch 41 is in the non-conductive state.

SW64 shows a state of pull-up switch 64E. To put it another way, a period in which SW64 is “ON” indicates that pull-up switch 64E is in the conductive state, and a period in which SW64 is “OFF” indicates that pull-up switch 64E is in the non-conductive state.

SW61 shows a state of first reset switch 61D. To put it another way, a period in which SW61 is “ON” indicates that first reset switch 61D is in the conductive state, and a period in which SW61 is “OFF” indicates that first reset switch 61D is in the non-conductive state.

As shown in FIG. 17, the solid-state imaging device according to Variation 2 including sample-and-hold circuit 10E thus configured may expand a dynamic range of first buffer 21 by, for example, (i) causing pull-up switch 64E and first output switch 41 to be in the non-conductive state during a reset period in which first reset switch 61D is in the conductive state, and (ii) causing pull-up switch 64E to be in the conductive state during a readout period in which first output switch 41 is in the conductive state.

### EMBODIMENT 2

The following describes a solid-state imaging device according to Embodiment 2 configured by changing part of the configuration of solid-state imaging device 1 according to Embodiment 1.

With regard to the solid-state imaging device according to Embodiment 2, since the same constituent elements as those of solid-state imaging device 1 are already described, they are assigned the same reference signs and detailed descriptions thereof are omitted, and the differences from solid-state imaging device 1 are mainly described.

### 2.1. Configuration of solid-state imaging device

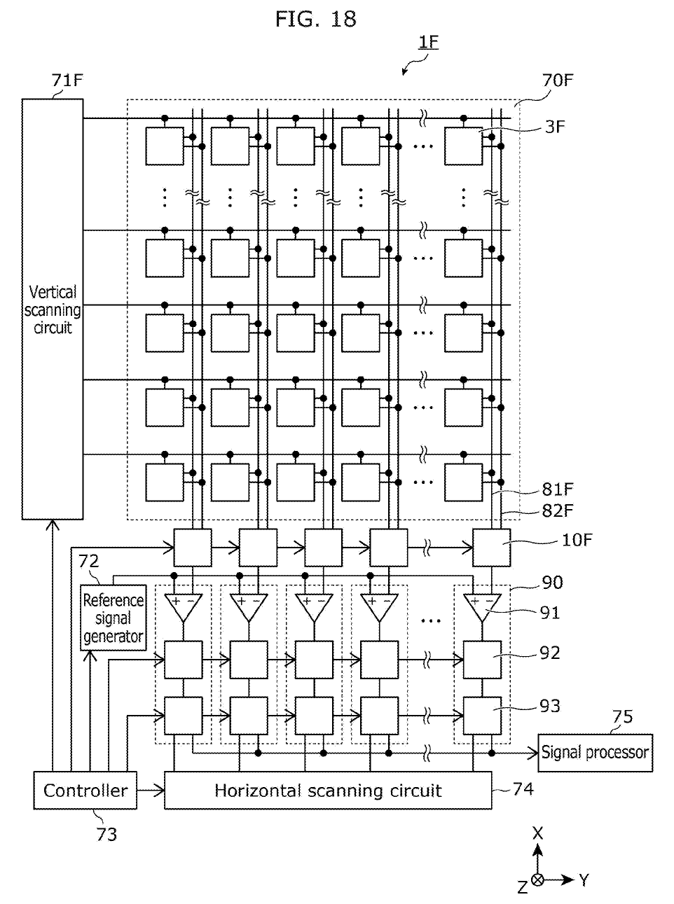

FIG. 18 is a block diagram illustrating a configuration of solid-state imaging device 1F according to Embodiment 2.

As shown in FIG. 18, solid-state imaging device 1F is configured by replacing pixel array 70, vertical scanning circuit 71, the plurality of vertical signal lines 80, and the plurality of sample-and-hold circuits 10 included in solid-state imaging device 1 according to Embodiment 1 with pixel array 70F, vertical scanning circuit 71F, a plurality of first vertical signal lines 81F and a plurality of second vertical signal lines 82F, and a plurality of sample-and-hold circuits 10F, respectively.

In addition, pixel array 70F is configured by replacing the plurality of pixels 3 included in pixel array 70 with a plurality of pixels 3F.

Pixel 3F includes: a photoelectric converter that converts exposed light into signal charge; and a signal charge holder that holds the signal charge generated by the photoelectric converter. Pixel 3F outputs a plurality of pixel signals corresponding to the signal charge held in the signal charge holder and having different gains from one another.

The following description assumes that pixel 3F outputs two pixel signals that are a first pixel signal and a second pixel signal having a gain higher than a gain of the first pixel signal.

Hereinafter, a first pixel signal is also referred to as a low conversion gain (LCG) signal or simply as LCG. Additionally, a second pixel signal is also referred to as a high conversion gain (HCG) signal or simply as HCG.

Each of the plurality of first vertical signal lines 81F extends in a column direction (an X-axis direction in FIG. 18) of pixel array 70F, is connected to m pixels 3F arranged in the column direction of pixel array 70F, and is for transmitting the first pixel signal outputted from at least one of m pixels 3F connected.

In other words, the number of the plurality of first vertical signal lines 81F included in solid-state imaging device 1F is n that is equal to the number of columns of pixel array 70F or an integer multiple of n. Here, the following description assumes that the number of the plurality of first vertical signal lines 81F is n that is equal to the number of the columns of pixel array 70F.

Each of the plurality of second vertical signal lines 82F extends in the column direction of pixel array 70F, is connected to m pixels 3F arranged in the column direction of pixel array 70F, and is for transmitting the second pixel signal outputted from at least one of m pixels 3F connected.

In other words, the number of the plurality of second vertical signal lines 82F included in solid-state imaging device 1F is n that is equal to the number of the columns of pixel array 70F or an integer multiple of n. Here, the following description assumes that the number of the plurality of second vertical signal lines 82F is n that is equal to the number of the columns of pixel array 70F.

By performing, for each row, sequential selective scan on the plurality of pixels 3F included in pixel array 70F, vertical scanning circuit 71F causes each of n pixels 3F belonging to a row to be scanned to simultaneously output the first pixel signal to a corresponding one of n first vertical signal lines 81F and simultaneously output the second pixel signal to a corresponding one of n second vertical signal lines 82F.

The plurality of sample-and-hold circuits 10F correspond to the plurality of first vertical signal lines 81F and the plurality of second vertical signal lines 82F on a one-to-one basis, and each of the plurality of sample-and-hold circuits 10F holds the first pixel signal transmitted through corresponding first vertical signal line 81F and the second pixel signal transmitted through corresponding second vertical signal line 82F.

In other words, the number of the plurality of sample-and-hold circuits 10F included in solid-state imaging device 1F is n that is equal to the number of the columns of pixel array 70F or an integer multiple of n. Here, the following description assumes that the number of the plurality of sample-and-hold circuits 10F is n that is equal to the number of the columns of pixel array 70F.

Sample-and-hold circuit 10F includes: one or more capacitors that are for holding first pixel signals and arranged in parallel to each other; and one or more capacitors that are for holding second pixel signals and arranged in parallel to each other. To put it another way, sample-and-hold circuit 10F makes it possible to hold one or more first pixel signals and one or more second pixel signals. In addition, sample-and-hold circuit 10F includes one or more buffers for buffering the one or more first pixel signals and the one or more second pixel signals that are held. Sample-and-hold circuit 10F outputs a signal corresponding to one of the one or more first pixel signals and the one or more second pixel signals that are held.

### 2.2. Configuration of sample-and-hold circuit

Hereinafter, a specific configuration of sample-and-hold circuit 10F is described.

As stated above, sample-and-hold circuit 10F includes: the one or more capacitors that are for holding the first pixel signals and arranged in parallel to each other; and the one or more capacitors that are for holding the second pixel signals and arranged in parallel to each other.

In the following description, a capacitor for holding first pixel signals is also referred to as an LCG capacitor, and a capacitor for holding second pixel signals is also referred to as an HCG capacitor.

First, a configuration of sample-and-hold circuit 10F when sample-and-hold circuit 10F includes one LCG capacitor and one HCG capacitor is described.

[2.2.A. Configuration of sample-and-hold circuit including one LCG capacitor and one HCG capacitor]

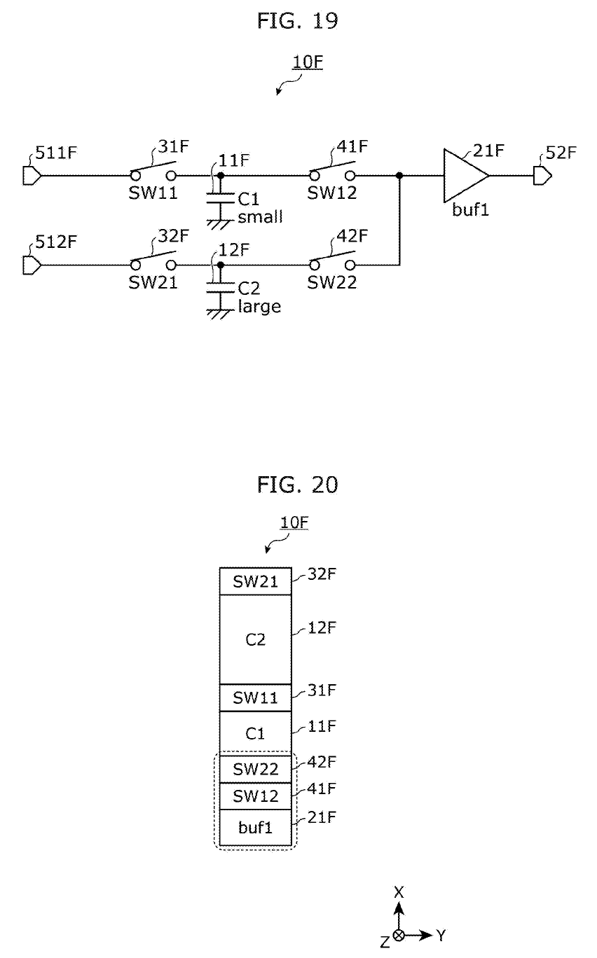

FIG. 19 is a circuit diagram illustrating an exemplary circuit configuration of sample-and-hold circuit 10F when sample-and-hold circuit 10F includes one LCG capacitor and one HCG capacitor.

As shown in FIG. 19, sample-and-hold circuit 10F includes first capacitor 11F, second capacitor 12F, first buffer 21F, first input switch 31F, second input switch 32F, first output switch 41F, second output switch 42F, input 511F, input 512F, and output 52F.

Input 511F is connected to first vertical signal line 81F.

Input 512F is connected to second vertical signal line 82F.

Output 52F is connected to AD conversion circuit 90.

First capacitor 11F is a capacitor for holding first pixel signals. In other words, first capacitor 11F is an LCG capacitor. First capacitor 11F is denoted by C1 in FIG. 19, the circuit diagrams and plan views to be described later, etc.

Second capacitor 12F is a capacitor for holding second pixel signals. In other words, second capacitor 12F is an HCG capacitor. First capacitor 11F has a capacitance smaller than a capacitance of second capacitor 12F. Second capacitor 12F is denoted by C2 in FIG. 19, the circuit diagrams and plan views to be described later, etc.

First buffer 21F is a buffer that has an output connected to output 52F, that is, an output connected to AD conversion circuit 90, and is for buffering the pixel signals held by first capacitor 11F or the pixel signals held by second capacitor 12F. First buffer 21F is denoted by buf1 in FIG. 19, the circuit diagrams and plan views to be described later, etc.

First input switch 31F is a switch that is connected to input 511F and first capacitor 11F and alternates between the conductive state and the non-conductive state to connect or disconnect input 511F and first capacitor 11F. In other words, first input switch 31F is a switch that is disposed in an electrical path between first vertical signal line 81F and first capacitor 11F, and alternates between the conducive state and the non-conductive state to connect or disconnect first vertical signal line 81F and first capacitor 11F. First input switch 31F is denoted by SW11 in FIG. 19, the circuit diagrams and plan views to be described later, etc.

Second input switch 32F is a switch that is connected to input 512F and second capacitor 12F and alternates between the conductive state and the non-conductive state to connect or disconnect input 512F and second capacitor 12F. In other words, second input switch 32F is a switch that is disposed in an electrical path between second vertical signal line 82F and second capacitor 12F, and alternates between the conducive state and the non-conductive state to connect or disconnect second vertical signal line 82F and second capacitor 12F. Second input switch 32F is denoted by SW21 in FIG. 19, the circuit diagrams and plan views to be described later, etc.

First output switch 41F is a switch that is connected to first capacitor 11F and an input of first buffer 21F and alternates between the conductive state and the non-conductive state to connect or disconnect first capacitor 11F and the input of first buffer 21F. In other words, first output switch 41F is a switch that is disposed in an electrical path between first capacitor 11F and the input of first buffer 21F, and alternates between the conductive state and the non-conductive state to connect or disconnect first capacitor 11F and the input of first buffer 21F. First output switch 41F is denoted by SW12 in FIG. 19, the circuit diagrams and plan views to be described later, etc.

Second output switch 42F is a switch that is connected to second capacitor 12F and the input of first buffer 21F and alternates between the conductive state and the non-conductive state to connect or disconnect second capacitor 12F and the input of first buffer 21F. In other words, second output switch 42F is a switch that is disposed in an electrical path between second capacitor 12F and the input of first buffer 21F, and alternates between the conductive state and the non-conductive state to connect or disconnect second capacitor 12F and the input of first buffer 21F. Second output switch 42F is denoted by SW22 in FIG. 19, the circuit diagrams and plan views to be described later, etc.

FIG. 20 is a plan-view schematic diagram illustrating an exemplary physical configuration of sample-and-hold circuit 10F shown in FIG. 19.

In FIG. 20, an X-axis direction is the column direction of pixel array 70F, and a Y-axis direction is the row direction of pixel array 70F. For this reason, FIG. 20 is a plan-view schematic diagram illustrating sample-and-hold circuit 10F in a plan view of pixel array 70F.

As shown in FIG. 20, in a plan view of sample-and-hold circuit 10F, that is, in the plan view of pixel array 70F, a distance between first output switch 41F and first buffer 21F in the column direction (the X-axis direction in FIG. 20) of pixel array 70F is shorter than a distance between second output switch 42F and first buffer 21F in the column direction of pixel array 70F.

Solid-state imaging device 1F including sample-and-hold circuit 10F thus configured makes it possible to cause a parasitic capacitance between first output switch 41F and the input of first buffer 21F in the electrical path between first capacitor 11F having a smaller capacitance and the input of first buffer 21F to be smaller than a parasitic capacitance between second output switch 42F and the input of first buffer 21F in the electrical path between second capacitor 12F having a larger capacitance and the input of first buffer 21F. Accordingly, it is possible to reduce the impact of charge redistribution caused by the operation of at least one of first output switch 41F or second output switch 42F.

Moreover, solid-state imaging device 1F including sample-and-hold circuit 10F thus configured includes sample-and-hold circuit 10F that includes first capacitor 11F and second capacitor 12F arranged in parallel to each other.

Accordingly, solid-state imaging device 1F including sample-and-hold circuit 10F thus configured makes it possible to achieve the higher captured image quality while achieving the high-speed imaging operation.

It should be noted that sample-and-hold circuit 10F may further include inputs of one or more buffers and one or more reset switches for resetting one or more LCG capacitors and one or more HCG capacitors.

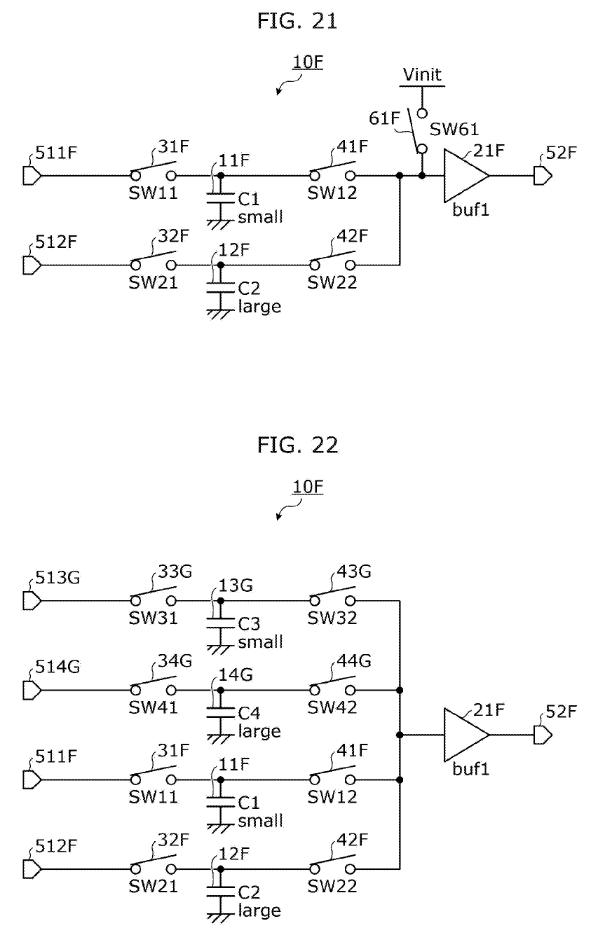

FIG. 21 is a circuit diagram illustrating an exemplary circuit configuration of sample-and-hold circuit 10F when sample-and-hold circuit 10F shown in FIG. 19 further includes first reset switch 61F for resetting the input of first buffer 21F, first capacitor 11F, and second capacitor 12F to initialization voltage Vinit.

First reset switch 61F is a switch that is connected to an output of an initialization power source that supplies initialization voltage Vinit and the input of first buffer 21F, and alternates between the conductive state and the non-conductive state to connect or disconnect the output of the initialization power source and the input of first buffer 21F. In other words, first reset switch 61F is a switch that is disposed in an electrical path between the output of the initialization power source and the input of first buffer 21F, and alternates between the conductive state and the non-conductive state to connect or disconnect the output of the initialization power source and the input of first buffer 21F. First reset switch 61F is denoted by SW61 in FIG. 21.

By causing first reset switch 61F to be in the conductive state, solid-state imaging device 1F including sample-and-hold circuit 10F thus configured makes it possible to reset the input of first buffer 21F to initialization voltage Vinit.

Next, a configuration of sample-and-hold circuit 10F when sample-and-hold circuit 10F includes two LCG capacitors arranged in parallel to each other and two HCG capacitors arranged in parallel to each other is described.

### 2.2.B. Configuration of sample-and-hold circuit including two LCG capacitors and two HCG capacitors

FIG. 22 is a circuit diagram illustrating an exemplary circuit configuration of sample-and-hold circuit 10F when sample-and-hold circuit 10F includes two LCG capacitors and two HCG capacitors.

As shown in FIG. 22, sample-and-hold circuit 10F is configured by adding, to sample-and-hold circuit 10F including the one LCG capacitor and the one HCG capacitor shown in FIG. 19, third capacitor 13G, fourth capacitor 14G, third input switch 33G, fourth input switch 34G, third output switch 43G, fourth output switch 44G, input 513G, and input 514G.

Input 513G is connected to first vertical signal line 81F.

Input 514G is connected to second vertical signal line 82F.

Third capacitor 13G is a capacitor for holding first pixel signals. In other words, third capacitor 13G is an LCG capacitor. Third capacitor 13G has a capacitance equal to a capacitance of first capacitor 11F. Third capacitor 13G is denoted by C3 in FIG. 22, the circuit diagrams and plan views to be described later, etc.

Fourth capacitor 14G is a capacitor for holding second pixel signals. In other words, fourth capacitor 14G is an HCG capacitor. Fourth capacitor 14G has a capacitance equal to a capacitance of second capacitor 12F. Fourth capacitor 14G is denoted by C4 in FIG. 22, the circuit diagrams and plan views to be described later, etc.

Third input switch 33G is a switch that is connected to input 513G and third capacitor 13G and alternates between the conductive state and the non-conductive state to connect or disconnect input 513G and third capacitor 13G. In other words, third input switch 33G is a switch that is disposed in an electrical path between first vertical signal line 81F and third capacitor 13G, and alternates between the conducive state and the non-conductive state to connect or disconnect first vertical signal line 81F and third capacitor 13G. Third input switch 33G is denoted by SW31 in FIG. 22, the circuit diagrams and plan views to be described later, etc.

Fourth input switch 34G is a switch that is connected to input 514G and fourth capacitor 14G and alternates between the conductive state and the non-conductive state to connect or disconnect input 514G and fourth capacitor 14G. In other words, fourth input switch 34G is a switch that is disposed in an electrical path between second vertical signal line 82F and fourth capacitor 14G, and alternates between the conducive state and the non-conductive state to connect or disconnect second vertical signal line 82F and fourth capacitor 14G. Fourth input switch 34G is denoted by SW41 in FIG. 22, the circuit diagrams and plan views to be described later, etc.

Third output switch 43G is a switch that is connected to third capacitor 13G and the input of first buffer 21F and alternates between the conductive state and the non-conductive state to connect or disconnect third capacitor 13G and the input of first buffer 21F. In other words, third output switch 43G is a switch that is disposed in an electrical path between third capacitor 13G and the input of first buffer 21F, and alternates between the conductive state and the non-conductive state to connect or disconnect third capacitor 13G and the input of first buffer 21F. Third output switch 43G is denoted by SW32 in FIG. 22, the circuit diagrams and plan views to be described later, etc.

Fourth output switch 44G is a switch that is connected to fourth capacitor 14G and the input of first buffer 21F and alternates between the conductive state and the non-conductive state to connect or disconnect fourth capacitor 14G and the input of first buffer 21F. In other words, fourth output switch 44G is a switch that is disposed in an electrical path between fourth capacitor 14G and the input of first buffer 21F, and alternates between the conductive state and the non-conductive state to connect or disconnect fourth capacitor 14G and the input of first buffer 21F. Fourth output switch 44G is denoted by SW42 in FIG. 22, the circuit diagrams and plan views to be described later, etc.

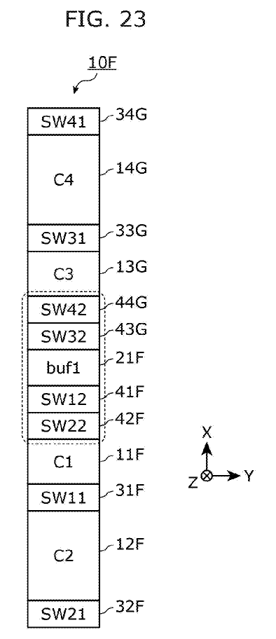

FIG. 23 is a plan-view schematic diagram illustrating an exemplary physical configuration of sample-and-hold circuit 10F shown in FIG. 22.

In FIG. 23, an X-axis direction is the column direction of pixel array 70F, and a Y-axis direction is the row direction of pixel array 70F. For this reason, FIG. 23 is a plan-view schematic diagram illustrating sample-and-hold circuit 10F in a plan view of pixel array 70F.

As shown in FIG. 23, in a plan view of sample-and-hold circuit 10F, that is, in the plan view of pixel array 70F, a distance between first output switch 41F and first buffer 21F in the column direction (the X-axis direction in FIG. 20) of pixel array 70F is shorter than a distance between second output switch 42F and first buffer 21F in the column direction of pixel array 70F; and a distance between third output switch 43G and first buffer 21F in the column direction of pixel array 70F is shorter than a distance between fourth output switch 44G and first buffer 21F in the column direction of pixel array 70F.

Solid-state imaging device 1F including sample-and-hold circuit 10F thus configured makes it possible to (i) cause a parasitic capacitance between first output switch 41F and the input of first buffer 21F in the electrical path between first capacitor 11F having a smaller capacitance and the input of first buffer 21F to be smaller than a parasitic capacitance between second output switch 42F and the input of first buffer 21F in the electrical path between second capacitor 12F having a larger capacitance and the input of first buffer 21F, and (ii) cause a parasitic capacitance between third output switch 43G and the input of first buffer 21F in the electrical path between third capacitor 13G having a smaller capacitance and the input of first buffer 21F to be smaller than a parasitic capacitance between fourth output switch 44G and the input of first buffer 21F in the electrical path between fourth capacitor 14G having a larger capacitance and the input of first buffer 21F. Accordingly, it is possible to reduce the impact of charge redistribution caused by the operation of at least one of first output switch 41F, second output switch 42F, third output switch 43G, or fourth output switch 44G.

Moreover, solid-state imaging device 1F including sample-and-hold circuit 10F thus configured includes sample-and-hold circuit 10F that includes first capacitor 11F, second capacitor 12F, third capacitor 13G, and fourth capacitor 14G arranged in parallel to each other.

Accordingly, solid-state imaging device 1F including sample-and-hold circuit 10F thus configured makes it possible to achieve the higher captured image quality while achieving the high-speed imaging operation.

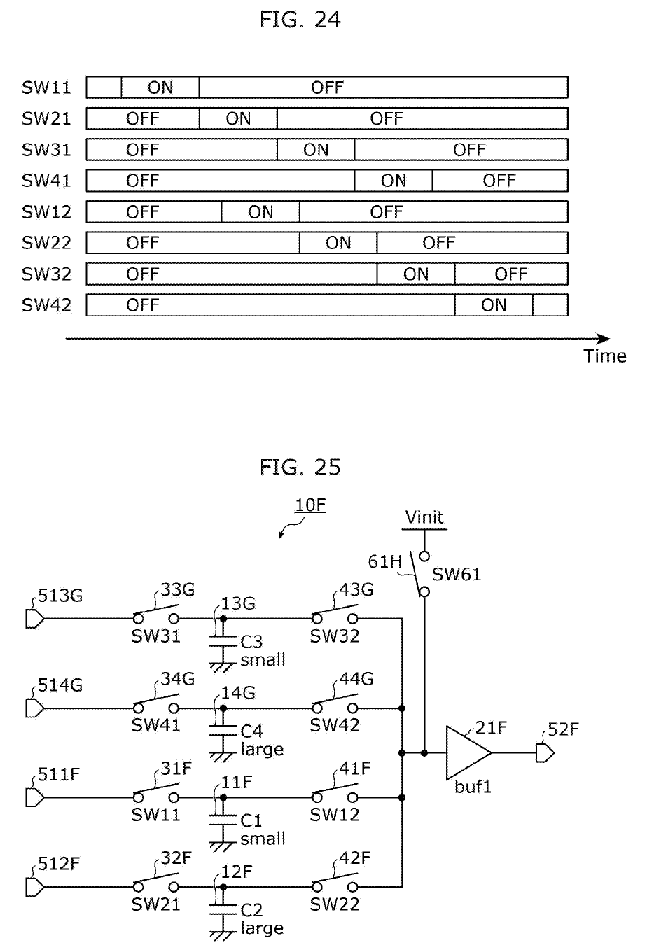

FIG. 24 is a timing chart for exemplary operations performed by solid-state imaging device 1F including sample-and-hold circuit 10F thus configured.

In FIG. 24, SW11 shows a state of first output switch 31F. To put it another way, a period in which SW11 is “ON” indicates that first input switch 31F is in the conductive state, and a period in which SW11 is “OFF” indicates that first input switch 31F is in the non-conductive state.

SW21 shows a state of second output switch 32F. To put it another way, a period in which SW21 is “ON” indicates that second input switch 32F is in the conductive state, and a period in which SW21 is “OFF” indicates that second input switch 32F is in the non-conductive state.

SW31 shows a state of third input switch 33G. To put it another way, a period in which SW31 is “ON” indicates that third input switch 33G is in the conductive state, and a period in which SW31 is “OFF” indicates that third input switch 33G is in the non-conductive state.

SW41 shows a state of fourth input switch 34G. To put it another way, a period in which SW41 is “ON” indicates that fourth input switch 34G is in the conductive state, and a period in which SW41 is “OFF” indicates that fourth input switch 34G is in the non-conductive state.

SW12 shows a state of first output switch 41F. To put it another way, a period in which SW12 is “ON” indicates that first output switch 41F is in the conductive state, and a period in which SW12 is “OFF” indicates that first output switch 41F is in the non-conductive state.

SW22 shows a state of second output switch 42F. To put it another way, a period in which SW22 is “ON” indicates that second output switch 42F is in the conductive state, and a period in which SW22 is “OFF” indicates that second output switch 42F is in the non-conductive state.

SW32 shows a state of third output switch 43G. To put it another way, a period in which SW32 is “ON” indicates that third output switch 43G is in the conductive state, and a period in which SW32 is “OFF” indicates that third output switch 43G is in the non-conductive state.

SW42 shows a state of fourth output switch 44G. To put it another way, a period in which SW42 is “ON” indicates that fourth output switch 44G is in the conductive state, and a period in which SW42 is “OFF” indicates that fourth output switch 44G is in the non-conductive state.

As shown in FIG. 24, solid-state imaging device 1F including sample-and-hold circuit 10F thus configured makes it possible to read out a first pixel signal and a second pixel signal from pixel 3F via pipeline control, by, for example, (i) causing sampling periods of sample-and-hold circuit 10F, that is, the period in which SW11 is “ON”, the period in which SW21 is “ON”, the period in which SW31 is “ON”, and the period in which SW41 is “ON”, to avoid overlapping one another, and (ii) causing output selection periods of sample-and-hold circuit 10F, that is, the period in which SW12 is “ON”, the period in which SW22 is “ON”, the period in which SW32 is “ON”, and the period in which SW42 is “ON”, to avoid overlapping one another.

Accordingly, solid-state imaging device 1F including sample-and-hold circuit 10F thus configured makes it possible to achieve the high-speed imaging operation.

It should be noted that sample-and-hold circuit 10F may further include inputs of one or more buffers and one or more reset switches for resetting one or more LCG capacitors and one or more HCG capacitors.

FIG. 25 is a circuit diagram illustrating an exemplary circuit configuration of sample-and-hold circuit 10F when sample-and-hold circuit 10F shown in FIG. 23 further includes first reset switch 61H for resetting the input of first buffer 21F, first capacitor 11F, second capacitor 12F, third capacitor 13G, and fourth capacitor 14G to initialization voltage Vinit.

First reset switch 61H is a switch that is connected to an output of an initialization power source that supplies initialization voltage Vinit and the input of first buffer 21F, and alternates between the conductive state and the non-conductive state to connect or disconnect the output of the initialization power source and the input of first buffer 21F. In other words, first reset switch 61H is a switch that is disposed in an electrical path between the output of the initialization power source and the input of first buffer 21F, and alternates between the conductive state and the non-conductive state to connect or disconnect the output of the initialization power source and the input of first buffer 21F. First reset switch 61H is denoted by SW61 in FIG. 25.

By causing first reset switch 61H to be in the conductive state, solid-state imaging device 1F including sample-and-hold circuit 10F thus configured makes it possible to reset the input of first buffer 21F to initialization voltage Vinit.

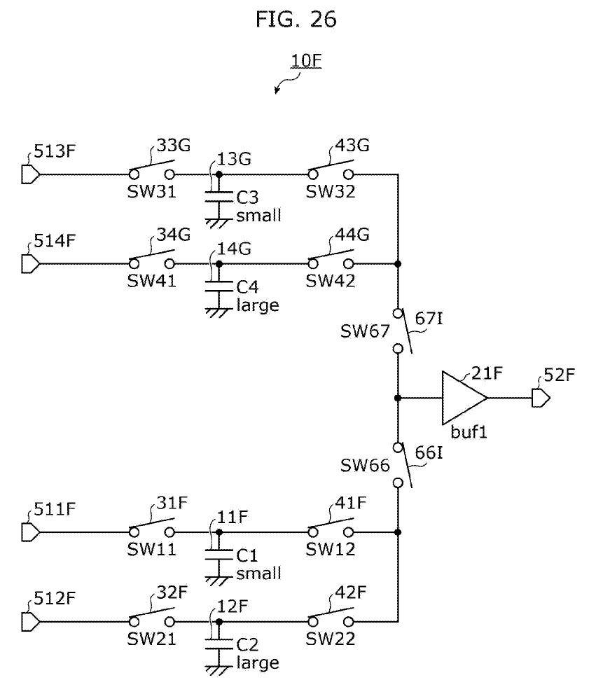

FIG. 26 is a circuit diagram illustrating an exemplary circuit configuration of sample-and-hold circuit 10F when sample-and-hold circuit 10F shown in FIG. 23 further includes first selector switch 66I disposed in an electrical path between (i) first output switch 41F and second output switch 42F and (ii) first buffer 21F, and second selector switch 67I disposed in an electrical path between (i) third output switch 43G and fourth output switch 44G and (ii) first buffer 21F.

First selector switch 66I is a switch that is connected to first output switch 41F, second output switch 42F, and first buffer 21F and alternates between the conductive state and the non-conductive state to connect or disconnect (i) first output switch 41F and second output switch 42F and (ii) first buffer 21F. In other words, first selector switch 66I is a switch that is disposed in the electrical path between (i) first output switch 41F and second output switch 42F and (ii) first buffer 21F, and alternates between the conductive state and the non-conductive state to connect or disconnect (i) first output switch 41F and second output switch 42F and (ii) first buffer 21F. First selector switch 66I is denoted by SW66 in FIG. 26.

Second selector switch 67I is a switch that is connected to third output switch 43G, fourth output switch 44G, and first buffer 21F and alternates between the conductive state and the non-conductive state to connect or disconnect (i) third output switch 43G and fourth output switch 44G and (ii) first buffer 21F. In other words, second selector switch 67I is a switch that is disposed in the electrical path between (i) third output switch 43G and fourth output switch 44G and (ii) first buffer 21F, and alternates between the conductive state and the non-conductive state to connect or disconnect (i) third output switch 43G and fourth output switch 44G and (ii) first buffer 21F. Second selector switch 67I is denoted by SW67 in FIG. 26.

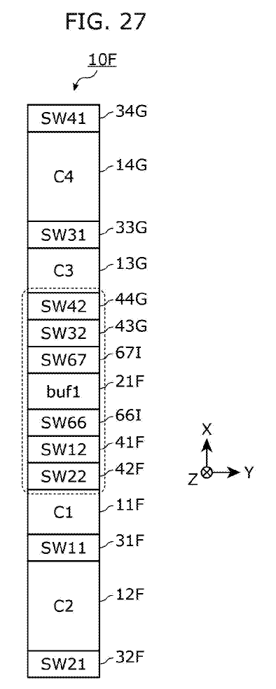

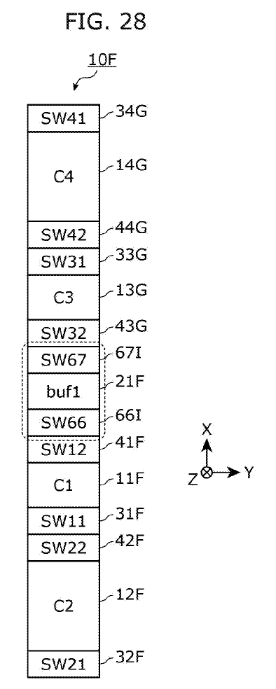

FIG. 27 is a plan-view schematic diagram illustrating an exemplary physical configuration of sample-and-hold circuit 10F shown in FIG. 26. FIG. 28 is a plan-view schematic diagram illustrating another exemplary physical configuration of sample-and-hold circuit 10F shown in FIG. 26.

In FIG. 27 and FIG. 28, an X-axis direction is the column direction of pixel array 70F, and a Y-axis direction is the row direction of pixel array 70F. For this reason, FIG. 27 and FIG. 28 are each a plan-view schematic diagram illustrating sample-and-hold circuit 10F in a plan view of pixel array 70F.

As shown in FIG. 27 and FIG. 28, in a plan view of sample-and-hold circuit 10F, that is, in the plan view of pixel array 70F, first selector switch 66I and first buffer 21F are adjacent to each other in the column direction (the X-axis direction in FIG. 26 and FIG. 27) of pixel array 70F, and second selector switch 67I and first buffer 21F are adjacent to each other in the column direction of pixel array 70F.

Solid-state imaging device 1F including sample-and-hold circuit 10F thus configured makes it possible to reduce a parasitic capacitance in an electrical path between (i) third output switch 43G and fourth output switch 44G and (ii) the input of first buffer 21F, and a parasitic capacitance in an electrical path between (i) first output switch 41F and second output switch 42F and (ii) the input of first buffer 21F, compared to a configuration without first selector switch 66I and second selector switch 67I (e.g., solid-state imaging device 1F including sample-and-hold circuit 10F configured as shown in FIG. 26).

Accordingly, solid-state imaging device 1F including sample-and-hold circuit 10F thus configured makes it possible to achieve the higher captured image quality while achieving the high-speed imaging operation.

[2.2.C. Configuration of sample-and-hold circuit including 2 + k (k is an integer greater than or equal to 1) LCG capacitors and 2 + k HCG capacitors]

Sample-and-hold circuit 10F including 2 + k LCG capacitors and 2 + k HCG capacitors is achieved by further providing k circuit groups in parallel, for example, in sample-and-hold circuit 10F shown in FIG. 22, the k circuit groups each including third capacitor 13G, fourth capacitor 14G, third input switch 33G, fourth input switch 34G, third output switch 43G, fourth output switch 44G, input 513G, and input 514G.

At this time, in each of the k circuit groups further provided, with regard to a relative positional relationship among first buffer 21F, third output switch 43G, and fourth output switch 44G included in the circuit group, in the plan view of sample-and-hold circuit 10F, that is, in the plan view of pixel array 70F, the distance between third output switch 43G and first buffer 21F in the column direction of pixel array 70F is maintained to be shorter than the distance between fourth output switch 44G and first buffer 21F in the column direction of pixel array 70F.

Additionally, sample-and-hold circuit 10F including 2 + k LCG capacitors and 2 + k HCG capacitors is achieved by further providing k circuit groups in parallel, for example, in sample-and-hold circuit 10F shown in FIG. 25, the k circuit groups each including third capacitor 13G, fourth capacitor 14G, third input switch 33G, fourth input switch 34G, third output switch 43G, fourth output switch 44G, input 513G, and input 514G.

At this time, in each of the k circuit groups further provided, with regard to a relative positional relationship among first buffer 21F, third output switch 43G, and fourth output switch 44G included in the circuit group, in the plan view of sample-and-hold circuit 10F, that is, in the plan view of pixel array 70F, the distance between third output switch 43G and first buffer 21F in the column direction of pixel array 70F is maintained to be shorter than the distance between fourth output switch 44G and first buffer 21F in the column direction of pixel array 70F.

### 2.3. Operation of solid-state imaging device

Hereinafter, the operation of solid-state imaging device 1F thus configured is described.

Here, the following description illustrates, as an example, solid-state imaging device 1F when sample-and-hold circuit 10F included in solid-state imaging device 1F is configured to include the two LCG capacitors, the two HCG capacitors, and the one reset switch shown in FIG. 25.

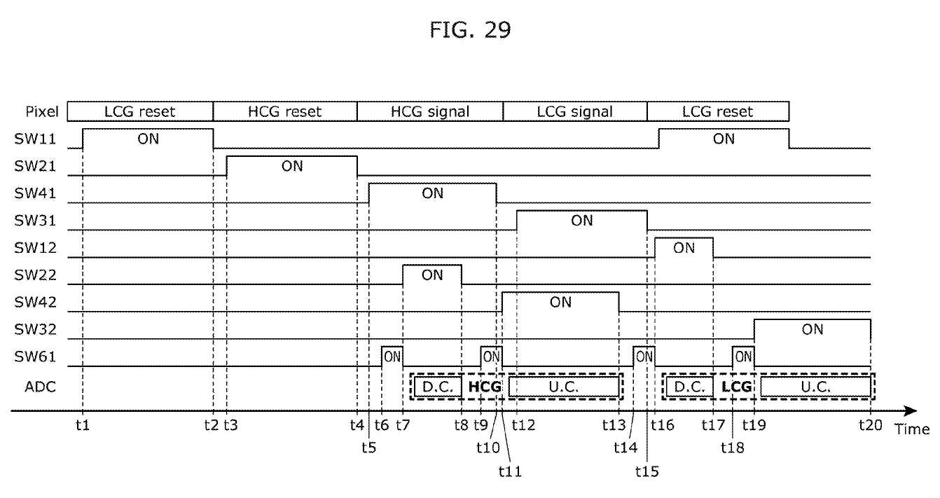

FIG. 29 is a timing chart for second readout pipeline control processing performed by solid-state imaging device 1F.

The second readout pipeline control processing is processing for reading out a first pixel signal (an LCG signal) and a second pixel signal (an HCG signal) from pixel 3F in the reset state and a first pixel signal (an LCG signal) and a second pixel signal (an HCG signal) from pixel 3F in the exposure state via pipeline control, to perform digital correlated double sampling.

Hereinafter, the first pixel signal of pixel 3F in the reset state is also referred to as an LCG reset level or an LCG dark level; the first pixel signal of pixel 3F in the exposure state is also referred to as an LCG signal level; the second pixel signal of pixel 3F in the reset state is also referred to as an HCG reset level or an HCG dark level; and the second pixel signal of pixel 3F in the exposure state is also referred to as an HCG signal level.

In FIG. 29, SW11 denotes a control signal for first input switch 31F and denotes a control signal for connecting first vertical signal line 81F and first capacitor 11F at the high logic level and disconnecting first vertical signal line 81F and first capacitor 11F at the low logic level.

SW21 denotes a control signal for second input switch 32F and denotes a control signal for connecting second vertical signal line 82F and second capacitor 12F at the high logic level and disconnecting second vertical signal line 82F and second capacitor 12F at the low logic level.

SW41 denotes a control signal for fourth input switch 34G and denotes a control signal for connecting second vertical signal line 82F and fourth capacitor 14G at the high logic level and disconnecting second vertical signal line 82F and fourth capacitor 14G at the low logic level.

SW31 denotes a control signal for third input switch 33G and denotes a control signal for connecting first vertical signal line 81F and third capacitor 13G at the high logic level and disconnecting first vertical signal line 81F and third capacitor 13G at the low logic level.

SW12 denotes a control signal for first output switch 41F and denotes a control signal for connecting first capacitor 11F and the input of first buffer 21F at the high logic level and for disconnecting first capacitor 11F and the input of first buffer 21F at the low logic level.

SW22 denotes a control signal for second output switch 42F and denotes a control signal for connecting second capacitor 12F and the input of first buffer 21F at the high logic level and for disconnecting second capacitor 12F and the input of first buffer 21F at the low logic level.

SW42 denotes a control signal for fourth output switch 44G and denotes a control signal for connecting fourth capacitor 14G and the input of first buffer 21F at the high logic level and for disconnecting fourth capacitor 14G and the input of first buffer 21F at the low logic level.

SW32 denotes a control signal for third output switch 43G and denotes a control signal for connecting third capacitor 13G and the input of first buffer 21F at the high logic level and for disconnecting third capacitor 13G and the input of first buffer 21F at the low logic level.

SW61 denotes a control signal for first reset switch 61H and denotes a control signal for connecting the output of the initialization power source and the input of first buffer 21F at the high logic level and disconnecting the output of the initialization power source and the input of first buffer 21F at the low logic level.

ADC denotes an operation performed by AD conversion circuit 90, D.C. (DownCount) denotes a dark level readout operation, and U.C. (UpCount) denotes a signal level readout operation.

As shown in FIG. 29, at time t1, by setting control signal SW11 to the high logic level, solid-state imaging device 1F causes first capacitor 11F to obtain an LCG dark level of pixel 3F. A high logic level period of control signal SW11 continues until time t2.

Next, at time t3, by setting control signal SW21 to the high logic level, solid-state imaging device 1F causes second capacitor 12F to obtain an HCG dark level of pixel 3F. A high logic level period of control signal SW21 continues until time t4.

Then, at time t5, by setting control signal SW41 to the high logic level, solid-state imaging device 1F causes fourth capacitor 14G to obtain an HCG signal level of pixel 3F. A high logic level period of control signal SW41 continues until time t10.

After that, at time t6, by setting control signal SW61 to the high logic level, solid-state imaging device 1F resets the input of first buffer 21F to initialization voltage Vinit. A high logic level period of control signal SW61 continues until time t7.

Next, at time t7, by setting control signal SW22 to the high logic level, solid-state imaging device 1F outputs, to the input of first buffer 21F, the HCG dark level of pixel 3F obtained and held by second capacitor 12F. In that case, first buffer 21F outputs, to AD conversion circuit 90, a signal corresponding to the HCG dark level obtained and held by second capacitor 12F. Under those circumstances, AD conversion circuit 90 performs AD conversion on the signal outputted from first buffer 21F, that is, AD conversion circuit 90 reads out the HCG dark level of pixel 3F. A high logic level period of control signal SW22 continues until time t8.

Then, at time t9, by setting control signal SW61 to the high logic level, solid-state imaging device 1F resets the input of first buffer 21F to initialization voltage Vinit. A high logic level period of control signal SW61 continues until time t11.

After that, at time t11, by setting control signal SW42 to the high logic level, solid-state imaging device 1F outputs, to the input of first buffer 21F, the HCG signal level of pixel 3F obtained and held by fourth capacitor 14G. In that case, first buffer 21F outputs, to AD conversion circuit 90, a signal corresponding to the HCG signal level obtained and held by fourth capacitor 14G. Under those circumstances, AD conversion circuit 90 performs AD conversion on the signal outputted from first buffer 21F, that is, AD conversion circuit 90 reads out the HCG signal level of pixel 3F. A high logic level period of control signal SW42 continues until time t13.

Next, at time t12, by setting control signal SW31 to the high logic level, solid-state imaging device 1F causes third capacitor 13G to obtain an LCG signal level of pixel 3F. A high logic level period of control signal SW31 continues until time t15.

Then, at time t14, by setting control signal SW61 to the high logic level, solid-state imaging device 1F resets the input of first buffer 21F to initialization voltage Vinit. A high logic level period of control signal SW61 continues until time t16.

After that, at time t16, by setting control signal SW12 to the high logic level, solid-state imaging device 1F outputs, to the input of first buffer 21F, the LCG dark level of pixel 3F obtained and held by first capacitor 11F. In that case, first buffer 21F outputs, to AD conversion circuit 90, a signal corresponding to the LCG dark level obtained and held by first capacitor 11F. Under those circumstances, AD conversion circuit 90 performs AD conversion on the signal outputted from first buffer 21F, that is, AD conversion circuit 90 reads out the LCG dark level of pixel 3F. A high logic level period of control signal SW12 continues until time t17.

Next, at time t18, by setting control signal SW61 to the high logic level, solid-state imaging device 1F resets the input of first buffer 21F to initialization voltage Vinit. A high logic level period of control signal SW61 continues until time t19.

Then, at time t19, by setting control signal SW32 to the high logic level, solid-state imaging device 1F outputs, to the input of first buffer 21F, the LCG signal level of pixel 3F obtained and held by third capacitor 13G. In that case, first buffer 21F outputs, to AD conversion circuit 90, a signal corresponding to the LCG signal level obtained and held by third capacitor 13G. Under those circumstances, AD conversion circuit 90 performs AD conversion on the signal outputted from first buffer 21F, that is, AD conversion circuit 90 reads out the LCG signal level of pixel 3F. A high logic level period of control signal SW32 continues until time t20.

As shown in FIG. 29, control signals SW11, SW21, SW31, and SW41 do not transition to the high logic level at the same time.

Moreover, immediately before control signals SW12, SW22, SW32, and SW42 transition to the high logic level, the input of first buffer 21F is reset to initialization voltage Vinit.

Furthermore, while the input of first buffer 21F is reset to initialization voltage Vinit, control signals SW12, SW22, SW23, and SW24 do not transition to the high logic level.

### Further Remarks

Embodiments 1 and 2 and Variations 1 and 2 are described above as examples of the techniques disclosed in the present Specification. However, the present disclosure is not limited to these embodiments and variations. The scope of one or more aspects of the present disclosure may include forms obtained by making various modifications to the embodiments or variations that can be conceived by a person skilled in the art, or forms obtained by combining constituent elements in different embodiments or variations, as long as the forms do not depart from the essence of the present disclosure.

(1) In Embodiment 2, pixel 3F outputs the two-pixel signals that are the first pixel signal (the LCG pixel signal) and the second pixel signal (the HCG pixel signal) each having a different gain.

However, pixel 3F need not be configured to output two pixel signals each having a different gain, and may be configured to output three or more pixel signals each having a different gain.

For example, pixel 3F may be configured to output three pixel signals that include a third pixel signal (hereinafter also referred to as a MCG pixel signal) having a gain that is higher than the gain of the first pixel signal (the LCG pixel signal) and lower than the gain of the second pixel signal (the HCG pixel signal), in addition to the first pixel signal (the LCG pixel signal) and the second pixel signal (the HCG pixel signal).

In this case, solid-state imaging device 1F further includes a plurality of third vertical signal lines each of which extends in the column direction (the X-axis direction in FIG. 18) of pixel array 70F, is connected to m pixels 3F arranged in the column direction of pixel array 70F, and is for transmitting a third pixel signal outputted from at least one of m pixels 3F connected.

Additionally, in this case, each of the plurality of sample-and-hold circuits 10F further includes one or more capacitors (MCG capacitors) that correspond to the plurality of third vertical signal lines on a one-to-one basis, are for holding third pixel signals transmitted through corresponding third vertical signal lines, and are arranged in parallel to each other, the one or more capacitors (the MCG capacitors) having a capacitance that is larger than a capacitance of the one or more LCG capacitors for holding the first pixel signals and smaller than a capacitance of the one or more HCG capacitors for holding the second pixel signals.

(2) In Variation 1, sample-and-hold circuit 10D configured by adding, to sample-and-hold circuit 10 according to Embodiment 1, fixed voltage output circuit 65D and first reset switch 61D is described with reference to FIG. 15.

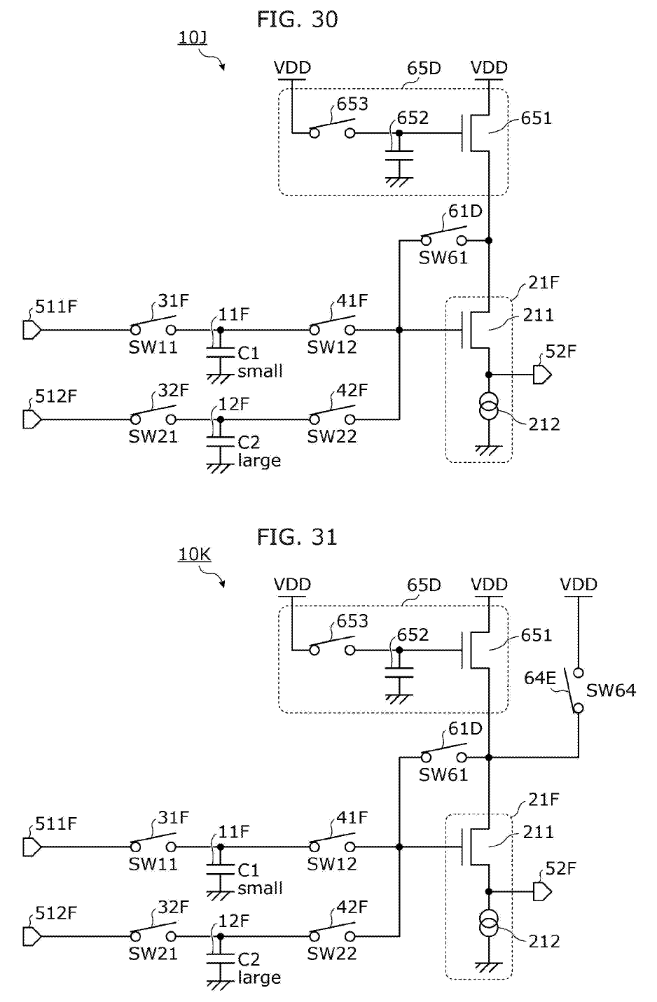

In the same manner, as illustrated in FIG. 30, it is also conceivable that sample-and-hold circuit 10J is configured by adding, to sample-and-hold circuit 10F according to Embodiment 2, fixed voltage output circuit 65D and first reset switch 61D.

(3) In Variation 2, sample-and-hold circuit 10E configured by adding pull-up switch 64E to sample-and-hold circuit 10D according to Variation 1 is described with reference to FIG. 16.

In the same manner, as illustrated in FIG. 31, it is also conceivable that sample-and-hold circuit 10K is configured by adding pull-up switch 64E to sample-and-hold circuit 10J illustrated in FIG. 30.

Although only some exemplary embodiments of the present disclosure have been described in detail above, those skilled in the art will readily appreciate that many modifications are possible in the exemplary embodiments without materially departing from the novel teachings and advantages of the present disclosure. Accordingly, all such modifications are intended to be included within the scope of the present disclosure.

### Industrial Applicability

The present disclosure is broadly applicable to, for example, solid-state imaging devices that capture images.

1. A solid-state imaging device comprising:
a pixel array in which a plurality of pixels are arranged in rows and columns;
a vertical signal line through which a pixel signal outputted from at least one of the plurality of pixels is transmitted, the vertical signal line extending in a column direction of the pixel array;
a sample-and-hold circuit that holds the pixel signal transmitted through the vertical signal line; and
an analog-to-digital (AD) conversion circuit that performs AD conversion on the pixel signal held by the sample-and-hold circuit,
wherein the sample-and-hold circuit includes:
a first capacitor;
a second capacitor that has a capacitance equal to a capacitance of the first capacitor;
a first buffer that has an output connected to the AD conversion circuit;
a first input switch that is disposed in an electrical path between the vertical signal line and the first capacitor;
a second input switch that is disposed in an electrical path between the vertical signal line and the second capacitor;
a first output switch that is disposed in an electrical path between the first capacitor and an input of the first buffer; and
a second output switch that is disposed in an electrical path between the second capacitor and the input of the first buffer, and
in a plan view of the pixel array:
the first output switch and the first buffer are adjacent to each other in the column direction; and
the second output switch and the first buffer are adjacent to each other in the column direction.

2. The solid-state imaging device according to claim 1,
wherein the sample-and-hold circuit further includes:
a third capacitor that has a capacitance equal to the capacitance of the first capacitor;
a fourth capacitor that has a capacitance equal to the capacitance of the first capacitor;
a second buffer that has an output connected to the AD conversion circuit;
a third input switch that is disposed in an electrical path between the vertical signal line and the third capacitor;
a fourth input switch that is disposed in an electrical path between the vertical signal line and the fourth capacitor;
a third output switch that is disposed in an electrical path between the third capacitor and an input of the second buffer; and
a fourth output switch that is disposed in an electrical path between the fourth capacitor and the input of the second buffer, and
in the plan view of the pixel array:
the third output switch and the second buffer are adjacent to each other in the column direction; and
the fourth output switch and the second buffer are adjacent to each other in the column direction.

3. A solid-state imaging device comprising:
a pixel array in which a plurality of pixels are arranged in rows and columns;
a vertical signal line through which a pixel signal outputted from at least one of the plurality of pixels is transmitted, the vertical signal line extending in a column direction of the pixel array;
a sample-and-hold circuit that holds the pixel signal transmitted through the vertical signal line; and
an analog-to-digital (AD) conversion circuit that performs AD conversion on the pixel signal held by the sample-and-hold circuit,
wherein the sample-and-hold circuit includes:
a first capacitor;
a second capacitor that has a capacitance equal to a capacitance of the first capacitor;
a third capacitor that has a capacitance equal to the capacitance of the first capacitor;
a first buffer that has an output connected to the AD conversion circuit;
a second buffer that has an output connected to the AD conversion circuit;
a first input switch that is disposed in an electrical path between the vertical signal line and the first capacitor;
a second input switch that is disposed in an electrical path between the vertical signal line and the second capacitor;
a third input switch that is disposed in an electrical path between the vertical signal line and the third capacitor;
a first output switch that is disposed in an electrical path between the first capacitor and an input of the first buffer;
a second output switch that is disposed in an electrical path between the second capacitor and the input of the first buffer;
a third output switch that is disposed in an electrical path between the second capacitor and an input of the second buffer; and
a fourth output switch that is disposed in an electrical path between the third capacitor and the input of the second buffer, and
in a plan view of the pixel array:
the first output switch and the first buffer are adjacent to each other in the column direction;
the second output switch and the first buffer are adjacent to each other in the column direction;
the third output switch and the second buffer are adjacent to each other in the column direction; and
the fourth output switch and the second buffer are adjacent to each other in the column direction.

4. The solid-state imaging device according to claim 3,
wherein the sample-and-hold circuit further includes:
a fourth capacitor that has a capacitance equal to the capacitance of the first capacitor;
a fifth capacitor that has a capacitance equal to the capacitance of the first capacitor;
a third buffer that has an output connected to the AD conversion circuit;
a fourth input switch that is disposed in an electrical path between the vertical signal line and the fourth capacitor;
a fifth input switch that is disposed in an electrical path between the vertical signal line and the fifth capacitor;
a fifth output switch that is disposed in an electrical path between the fourth capacitor and an input of the third buffer; and
a sixth output switch that is disposed in an electrical path between the fifth capacitor and the input of the third buffer, and
in the plan view of the pixel array:
the fifth output switch and the third buffer are adjacent to each other in the column direction; and
the sixth output switch and the third buffer are adjacent to each other in the column direction.

5. A solid-state imaging device comprising:
a pixel array in which a plurality of pixels are arranged in rows and columns;
a first vertical signal line through which a first pixel signal outputted from at least one of the plurality of pixels is transmitted, the first vertical signal line extending in a column direction of the pixel array;
a second vertical signal line through which a second pixel signal outputted from at least one of the plurality of pixels is transmitted, the second vertical signal line extending in the column direction, the second pixel signal having a gain higher than a gain of the first pixel signal;
a sample-and-hold circuit that holds the first pixel signal transmitted through the first vertical signal line and the second pixel signal transmitted through the second vertical signal line; and
an analog-to-digital (AD) conversion circuit that performs AD conversion on the first pixel signal and the second pixel signal that are held by the sample-and-hold circuit,
wherein the sample-and-hold circuit includes:
a first capacitor;
a second capacitor;
a buffer that has an output connected to the AD conversion circuit;
a first input switch that is disposed in an electrical path between the first vertical signal line and the first capacitor;
a second input switch that is disposed in an electrical path between the second vertical signal line and the second capacitor;
a first output switch that is disposed in an electrical path between the first capacitor and an input of the buffer; and
a second output switch that is disposed in an electrical path between the second capacitor and the input of the buffer,
in a plan view of the pixel array, a distance between the first output switch and the buffer in the column direction is shorter than a distance between the second output switch and the buffer in the column direction, and
the first capacitor has a capacitance smaller than a capacitance of the second capacitor.

6. The solid-state imaging device according to claim 5,
wherein the sample-and-hold circuit further includes:
a third capacitor that has a capacitance equal to the capacitance of the first capacitor;
a fourth capacitor that has a capacitance equal to the capacitance of the second capacitor;
a third input switch that is disposed in an electrical path between the first vertical signal line and the third capacitor;
a fourth input switch that is disposed in an electrical path between the second vertical signal line and the fourth capacitor;
a third output switch that is disposed in an electrical path between the third capacitor and the input of the buffer; and
a fourth output switch that is disposed in an electrical path between the fourth capacitor and the input of the buffer, and
in the plan view of the pixel array, a distance between the third output switch and the buffer in the column direction is shorter than a distance between the fourth output switch and the buffer in the column direction.

7. The solid-state imaging device according to claim 6,
wherein the sample-and-hold circuit further includes:
a first selector switch that is disposed in an electrical path between (i) the first output switch and the second output switch and (ii) the input of the buffer; and
a second selector switch that is disposed in an electrical path between (i) the third output switch and the fourth output switch and (ii) the input of the buffer, and
in the plan view of the pixel array:
the first selector switch and the buffer are adjacent to each other in the column direction; and
the second selector switch and the buffer are adjacent to each other in the column direction.

8. The solid-state imaging device according to claim 1,
wherein the sample-and-hold circuit further includes:
a fixed voltage output circuit that outputs, to the first buffer, an operating voltage for causing the first buffer to operate, the operating voltage having a fixed electric potential; and
a reset switch that is disposed in an electrical path between an output of the fixed voltage output circuit and the input of the first buffer.

9. The solid-state imaging device according to claim 3,
wherein the sample-and-hold circuit further includes:
a fixed voltage output circuit that outputs, to the first buffer and the second buffer, an operating voltage for causing the first buffer and the second buffer to operate, the operating voltage having a fixed electric potential;
a first reset switch that is disposed in an electrical path between an output of the fixed voltage output circuit and the input of the first buffer; and
a second reset switch that is disposed in an electrical path between the output of the fixed voltage output circuit and the input of the second buffer.

10. The solid-state imaging device according to claim 5,
wherein the sample-and-hold circuit further includes:
a fixed voltage output circuit that outputs, to the buffer, an operating voltage for causing the buffer to operate, the operating voltage having a fixed electric potential; and
a reset switch that is disposed in an electrical path between an output of the fixed voltage output circuit and the input of the buffer.

11. The solid-state imaging device according to claim 8,
wherein the fixed voltage output circuit includes:
a transistor that includes a drain connected to a power supply line and a source connected to the output of the fixed voltage output circuit;
an electric-potential-holding capacitor that is connected to a gate of the transistor; and
an electric-potential-holding switch that is disposed in an electrical path between the power supply line and the electric-potential-holding capacitor.

12. The solid-state imaging device according to claim 8,
wherein the sample-and-hold circuit further includes a pull-up or pull-down switch that adjusts the output of the fixed voltage output circuit.

13. The solid-state imaging device according to claim 9,
wherein the fixed voltage output circuit includes:
a transistor that includes a drain connected to a power supply line and a source connected to the output of the fixed voltage output circuit;
an electric-potential-holding capacitor that is connected to a gate of the transistor; and
an electric-potential-holding switch that is disposed in an electrical path between the power supply line and the electric-potential-holding capacitor.

14. The solid-state imaging device according to claim 9,
wherein the sample-and-hold circuit further includes a pull-up or pull-down switch that adjusts the output of the fixed voltage output circuit.

15. The solid-state imaging device according to claim 10,
wherein the fixed voltage output circuit includes:
a transistor that includes a drain connected to a power supply line and a source connected to the output of the fixed voltage output circuit;
an electric-potential-holding capacitor that is connected to a gate of the transistor; and
an electric-potential-holding switch that is disposed in an electrical path between the power supply line and the electric-potential-holding capacitor.

16. The solid-state imaging device according to claim 10,
wherein the sample-and-hold circuit further includes a pull-up or pull-down switch that adjusts the output of the fixed voltage output circuit.
